(19) United States
(12) Patent Application Publication
(10) Pub. No.: US 2024/0130156 A1
(43) Pub. Date: Apr. 18, 2024

(54) Light-Emitting Element and Display Panel

(71) Applicant: WUHAN CHINA STAR OPTOELECTRONICS SEMICONDUCTOR DISPLAY TECHNOLOGY CO., LTD., Wuhan (CN)

(72) Inventors: Yu ZHANG, Wuhan (CN); Li YUAN, Wuhan (CN); Munjae LEE, Wuhan (CN); Wenxu XIANYU, Wuhan (CN); Jie YANG, Wuhan (CN); Huizhen PIAO, Wuhan (CN); Mugyeom KIM, Wuhan (CN); Xianjie LI, Wuhan (CN); Jing HUANG, Wuhan (CN); Fang WANG, Wuhan (CN); Kailong WU, Wuhan (CN); Lin YANG, Wuhan (CN); Yu GU, Wuhan (CN); Mingzhou WU, Wuhan (CN); Jingyao SONG, Wuhan (CN); Danhua SHEN, Wuhan (CN); Guo CHENG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/474,404

(22) Filed: Sep. 26, 2023

(30) Foreign Application Priority Data
Sep. 26, 2022 (CN) 202211175695.8

(51) Int. Cl. H10K 50/19; H10K 50/15; H10K 50/16

(52) U.S. Cl. CPC H10K 50/19; H10K 50/156; H10K 50/16; H10K 2101/40

(57) ABSTRACT

A light-emitting element includes a pair of electrodes, a first light-emitting unit, a second light-emitting unit, and a charge generation layer. The first light-emitting unit, between the pair of electrodes, and the first light-emitting unit, includes a first light-emitting layer. The second light-emitting unit, between the pair of electrodes, includes a second light-emitting layer. A first luminescent layer includes a first main body material, a second main body material, a first guest material, and a first auxiliary material, and the first main body material forms a first excimer complex with the second main body material. A first excited triplet state energy level of the first auxiliary material is lower than a first excited triplet state energy level of the first excimer complex, and the first excited triplet state energy level of the first auxiliary material is higher than that of the first guest material.

### CROSS REFERENCE TO RELATED APPLICATION

This application claims priority to Chinese Application No. 202211175695.8, filed on Sep. 26, 2022. The entire disclosures of the above applications are incorporated herein by reference.

### FIELD OF THE INVENTION

The present disclosure relates to the field of display, more particularly, to a light-emitting element and a display panel.

### BACKGROUND

Organic light-emitting devices have attracted widespread attention in the display field due to their excellent properties such as thinness, lightweight, high-speed response to input signals, and the ability to drive at low direct current (DC) voltage. The display panel using organic light-emitting elements has excellent display capability, low power consumption, and superior bending performance. With the development of display panels with organic light-emitting elements, the improvement of user demand, the improvement of luminous efficiency, and the service life of organic light-emitting elements are key factors in enhancing the competitiveness of display panels including organic light-emitting elements. In theory, 100% internal quantum efficiency can be achieved in phosphorescent luminescent devices or thermally activated delayed fluorescent luminescent devices. However, due to the longer exciton lifetime, collisions between triplet excitons usually occur, thereby reducing the lifespan of organic luminescent devices. The luminescent efficiency and service life of organic luminescent devices usually compete, and extending the lifespan of organic luminescent devices requires sacrificing the luminescent efficiency of organic luminescent devices, For example, the method of designing and using small single-three-line state bandgap materials has a problem of twisting the energy transfer between the host material and the guest material, which leads to a decrease in the luminous efficiency of the light-emitting element.

Therefore, there is an urgent need for a light-emitting element and display panel to solve the technical problems.

### SUMMARY

One embodiment of the present disclosure is directed to a light-emitting element and a display panel, which can alleviate the technical problem of not being able to improve the lifespan of the light-emitting element while ensuring its luminous efficiency.

One embodiment of the present disclosure is directed to a light-emitting element. The light-emitting element comprises a pair of electrodes, a first light-emitting unit, a second light-emitting unit, and a charge generation layer. The pair of electrodes comprises a first electrode and a second electrode. The first light-emitting unit is located between the pair of electrodes, and the first light-emitting unit comprises a first light-emitting layer. The second light-emitting unit is located between the pair of electrodes, and the second light-emitting unit comprises a second light-emitting layer. The charge generation layer is located between the first light-emitting unit and the second light-emitting unit. Among them, a first luminescent layer comprises a first main body material, a second main body material, a first guest material, and a first auxiliary material, and the first main body material forms a first excimer complex with the second main body material. A first excited triplet state energy level of the first auxiliary material is lower than a first excited triplet state energy level of the first excimer complex, and the first excited triplet state energy level of the first auxiliary material is higher than a first excited triplet state energy level of the first guest material.

Optionally, the first light-emitting unit further comprises a first hole transport layer located on the side near the first electrode of the first light-emitting layer, and the first hole transport layer is in direct contact with the first light-emitting layer. The first hole transport layer comprises a first hole transport material, and a difference between a highest occupied molecular orbital energy level of the first hole transport material and a highest occupied molecular orbital energy level of the first excimer complex is less than 0.4 eV.

Optionally, a difference between a lowest unoccupied molecular orbital energy level of the first hole transport material and a lowest unoccupied molecular orbital energy level of the first excimer complex is greater than 0.2 eV.

Optionally, the first light-emitting unit comprises a first electron barrier layer and a first hole transport layer located on the side near the first electrode of the first electron barrier layer, the first electron barrier layer is in direct contact with the first light-emitting layer, and the first electron barrier layer is in direct contact with the first hole transport layer. The first electron barrier layer comprises a first electron barrier material, and a difference between a highest occupied molecular orbital energy level of the first electron barrier material and the highest occupied molecular orbital energy level of the first excimer complex is less than 0.3 eV. The first hole transport layer comprises a first hole transport material, and a difference between the highest occupied molecular orbital energy level of the first hole transport material and the highest occupied molecular orbital energy level of the first electron barrier material is less than 0.3 eV.

Optionally, the first light-emitting unit further comprises a first hole barrier layer located on the side of the first light-emitting layer away from the first electrode, and a first electron transport layer located on the side of the first hole barrier layer away from the first electrode, the first hole barrier layer is in direct contact with the first light-emitting layer, and the first hole barrier layer is in direct contact with the first electron transport layer. The first hole barrier layer comprises a first hole barrier material, and a difference between a lowest unoccupied molecular orbital energy level of the first hole barrier material and the lowest unoccupied molecular orbital energy level of the first excimer complex is less than 0.3 eV. The first electron transfer layer comprises a first electron transfer material, and a difference between a lowest unoccupied molecular orbital energy level of the first electron transfer material and the lowest unoccupied molecular orbital energy level of the first hole barrier material is less than 0.3 eV.

Optionally, the second light-emitting unit further comprises a second hole transport layer located on the side of the second light-emitting layer near the first electrode, and the second hole transport layer is in direct contact with the second light-emitting layer.

Optionally, the second light-emitting unit comprises a second electron barrier layer and a second hole transport layer located on the side near the first electrode of the second electron barrier layer, the second electron barrier layer is in direct contact with the second light-emitting layer, and the second electron barrier layer is in direct contact with the second hole transport layer.

Optionally, the second light-emitting unit is located on the side near the second electrode of the first light-emitting unit, and a mobility of the second hole transport layer is greater than a mobility of the first hole transport layer of the first light-emitting unit.

Optionally, the second light-emitting layer comprises a third main body material, a fourth main body material, a second guest material, and a second auxiliary material, wherein the third main body material forms a second excimer complex with the fourth main body material. A first excited triplet state energy level of the second auxiliary material is lower than a first excited triplet state energy level of the second excimer complex, and the first excited triplet state energy level of the second auxiliary material is higher than a first excited triplet state energy level of the second guest material.

Optionally, the second light-emitting unit is located on the side near the second electrode of the first light-emitting unit, the first light-emitting unit further comprises a first electron transfer layer located on the side near the second electrode of the first light-emitting layer, and the second light-emitting unit further comprises a second electron transfer layer located on the side near the second electrode of the second light-emitting layer. The mobility of the second electron transfer layer is smaller than a mobility of the first electron transfer layer.

Optionally, the charge generation layer comprises a first charge generation sublayer and a second charge generation sublayer located on the side away from the first electrode of the first charge generation sublayer. The first charge generation sublayer comprises a first doped material and a second doped material, the first doped material is different from the second doped material, and the second charge generation sublayer comprises a third doped material and a fourth doped material, the third doped material is different from the fourth doped material.

Optionally, a difference between a lowest unoccupied molecular orbital energy level of the first charge generation sublayer and a highest occupied molecular orbital energy level of a second charge generation sublayer is less than 3 eV.

Another embodiment of the present disclosure is also directed to a display panel, which comprises a light-emitting element. The light-emitting element comprises a pair of electrodes, a first light-emitting unit, a second light-emitting unit, and a charge generation layer. The pair of electrodes comprises a first electrode and a second electrode. The first light-emitting unit is located between the pair of electrodes, and the first light-emitting unit comprises a first light-emitting layer. The second light-emitting unit is located between the pair of electrodes, and the second light-emitting unit comprises a second light-emitting layer. The charge generation layer is located between the first light-emitting unit and the second light-emitting unit. Among them, a first luminescent layer comprises a first main body material, a second main body material, a first guest material, and a first auxiliary material, and the first main body material forms a first excimer complex with the second main body material. A first excited triplet state energy level of the first auxiliary material is lower than a first excited triplet state energy level of the first excimer complex, and the first excited triplet state energy level of the first auxiliary material is higher than a first excited triplet state energy level of the first guest material.

Optionally, the display panel includes a red light-emitting element, a green light-emitting element, and a blue light-emitting element. The green light-emitting element comprises a first green light-emitting unit electrode and a second green light-emitting unit electrode. The green light-emitting element further includes a first green light-emitting unit and a second green light-emitting unit. The first green light-emitting unit comprises a first green light-emitting layer and a first green light-emitting unit hole transport layer located on the side near the first green light-emitting unit electrode, the first green light-emitting layer is in direct contact with the first green light-emitting unit hole transport layer. The second green light-emitting unit comprises a second green light-emitting layer and a second green light-emitting unit hole transport layer located on the side of the second green light-emitting layer near the first green light-emitting unit electrode. The second green light-emitting layer is in direct contact with the second green light-emitting unit hole transport layer.

Optionally, the first light-emitting unit further comprises a first hole transport layer located on the side near the first electrode of the first light-emitting layer, and the first hole transport layer is in direct contact with the first light-emitting layer. The first hole transport layer comprises a first hole transport material, and a difference between a highest occupied molecular orbital energy level of the first hole transport material and a highest occupied molecular orbital energy level of the first excimer complex is less than 0.4 eV.

Optionally, the first light-emitting unit comprises a first electron barrier layer and a first hole transport layer located on the side near the first electrode of the first electron barrier layer, the first electron barrier layer is in direct contact with the first light-emitting layer, and the first electron barrier layer is in direct contact with the first hole transport layer. The first electron barrier layer comprises a first electron barrier material, and a difference between a highest occupied molecular orbital energy level of the first electron barrier material and the highest occupied molecular orbital energy level of the first excimer complex is less than 0.3 eV. The first hole transport layer comprises a first hole transport material, and a difference between the highest occupied molecular orbital energy level of the first hole transport material and the highest occupied molecular orbital energy level of the first electron barrier material is less than 0.3 eV.

Optionally, the first light-emitting unit further comprises a first hole barrier layer located on the side of the first light-emitting layer away from the first electrode, and a first electron transport layer located on the side of the first hole barrier layer away from the first electrode, the first hole barrier layer is in direct contact with the first light-emitting layer, and the first hole barrier layer is in direct contact with the first electron transport layer. The first hole barrier layer comprises a first hole barrier material, and a difference between a lowest unoccupied molecular orbital energy level of the first hole barrier material and the lowest unoccupied molecular orbital energy level of the first excimer complex is less than 0.3 eV. The first electron transfer layer comprises a first electron transfer material, and a difference between a lowest unoccupied molecular orbital energy level of the first electron transfer material and the lowest unoccupied molecular orbital energy level of the first hole barrier material is less than 0.3 eV.

Optionally, the second light-emitting unit further comprises a second hole transport layer located on the side of the second light-emitting layer near the first electrode, and the second hole transport layer is in direct contact with the second light-emitting layer.

Optionally, the second light-emitting unit comprises a second electron barrier layer and a second hole transport layer located on the side near the first electrode of the second electron barrier layer, the second electron barrier layer is in direct contact with the second light-emitting layer, and the second electron barrier layer is in direct contact with the second hole transport layer.

Optionally, the second light-emitting unit is located on the side near the second electrode of the first light-emitting unit, the first light-emitting unit further comprises a first electron transfer layer located on the side near the second electrode of the first light-emitting layer, and the second light-emitting unit further comprises a second electron transfer layer located on the side near the second electrode of the second light-emitting layer. The mobility of the second electron transfer layer is smaller than a mobility of the first electron transfer layer.

The present disclosure increases the path of energy transfer from the first excimer complex to the first guest material through the addition of a first auxiliary material, reduces energy loss during the energy transfer process, ensures the luminous efficiency of the light-emitting element, and prolongs its service life.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a schematic diagram of the luminescence principle of a first luminescent layer according to one embodiment of the present disclosure.

FIG. 2 is a schematic diagram of a light-emitting element according to one embodiment of the present disclosure.

FIG. 3 is a schematic diagram of a light-emitting element according to another embodiment of the present disclosure.

FIG. 4 is a schematic diagram of a light-emitting element according to still another embodiment of the present disclosure.

FIG. 5 is a schematic diagram of the time when the luminous intensity of the light-emitting according to one embodiment of the present disclosure decreases to 95% of the initial brightness under the same current density conditions.

FIG. 6 is a structural schematic diagram of a display panel according to one embodiment of the present disclosure.

### DESCRIPTION OF THE EMBODIMENTS

The service life and luminous efficiency of existing organic light-emitting devices are in a competitive relationship, which makes it difficult to ensure the luminous efficiency of organic light-emitting devices while improving their service life.

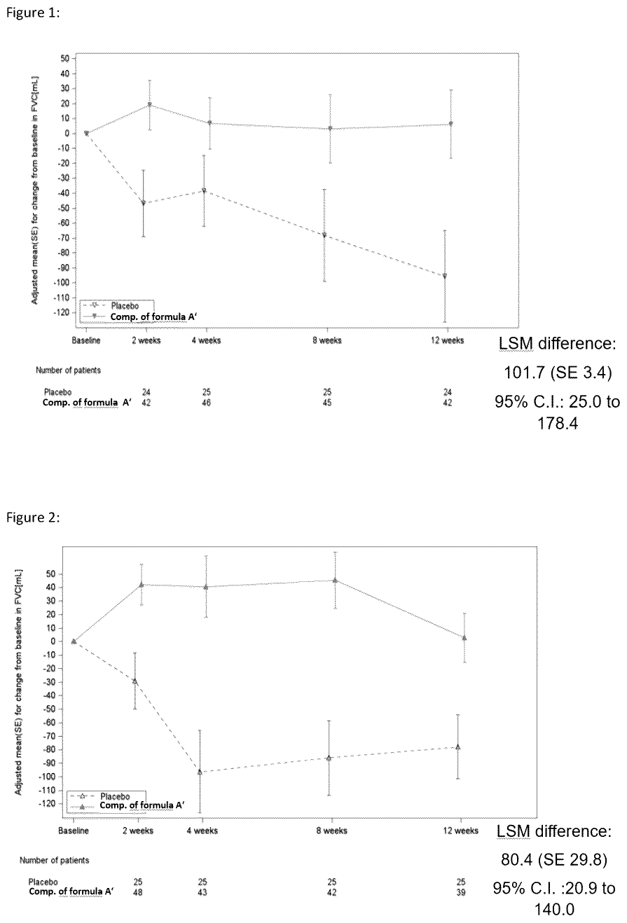

Please refer to FIGS. 1 to 4. One embodiment of the present disclosure is directed to a light-emitting element 101 comprises a pair of electrodes, a first light-emitting unit 101A, a second light-emitting unit 101B, and the charge generation layer 119. The pair of electrodes comprises a first electrode 102 and a second electrode 103. The first light-emitting unit 101A is located between the pair of electrodes, and the first light-emitting unit 101A comprises a first light-emitting layer 104. The second light-emitting unit 101B 20 is located between the pair of electrodes, and the second light-emitting unit 101B comprises a second light-emitting layer 105. The charge generation layer 119 is located between the first light-emitting unit 101A and the second light-emitting unit 101B. The first luminescent layer 104 comprises a first main body material, a second main body material, a first guest material, and a first auxiliary material, and the first main body material forms a first excimer complex with the second main body material. A first excited triplet state energy level of the first auxiliary material is lower than a first excited triplet state energy level of the first excimer complex, and the first excited triplet state energy level of the first auxiliary material is higher than a first excited triplet state energy level of the first guest material.

The embodiment of the present disclosure increases the path for energy transfer from the first excimer complex to the first guest material by setting the first luminescent unit 101A and the second luminescent unit 101B in the light-emitting element 101, and adding the first luminescent layer 104 in the first luminescent unit 101A to the first auxiliary material, and the first excited triplet state energy level of the first auxiliary material is between the first excimer complex and the first excited triplet state energy level of the first guest material, This reduces the energy loss during the energy transfer process, ensures the luminous efficiency of the light-emitting element 101, and extends the service life of the light-emitting element 101.

In this embodiment, the first main body material and the second main body material are the two materials with the highest content in the first luminescent layer 104. The volume fraction of the first and second main body materials in the first luminescent layer 104 accounts for 80% to 99.8% of the luminescent layer. The first guest material and the first auxiliary material are dispersed in the first host material and the second host material, with the first guest material accounting for 0.1% to 10% of the volume fraction of the first luminescent layer 104, and the first auxiliary material accounting for 0.1% to 10% of the volume fraction of the first luminescent layer 104. The dispersion of the first guest material and the first auxiliary material in the first host material and the second host material is beneficial for suppressing the crystallization of the first luminescent layer 104 and suppressing the concentration quenching caused by a high concentration of the first guest material and the first auxiliary material, thereby ensuring the luminous efficiency of the light-emitting element 101.

The general luminescence process of the luminescent layer in the light-emitting element is as follows:
(1) When electrons and holes recombine in the guest material molecule and the guest material molecule is in an excited state: when the excited state of the guest material molecule is the first excited triplet state (T1), the guest material molecule emits phosphorescence. When the excited state of the guest material molecule is the first excited singlet state (S1), the guest material molecule in the first excited singlet state transitions through the system to the first excited triplet state, and then the guest material molecule emits phosphorescence.
(2) When electrons and holes recombine in the host material molecule, and the host material molecule is in an excited state: when the excited state of the host material molecule is the first excited triplet state, the first excited triplet state energy level of the host material molecule is higher than the first excited triplet state energy level of the guest material molecule, and the excitation energy is transferred from the host material to the guest material. The guest material molecule is in the first excited triplet state, and the guest material molecule emits phosphorescence. At this point, although there is a possibility of energy transfer to the first excited singlet state of the guest material molecule, in most cases, the energy level of the first excited singlet state of the guest material molecule is higher than the energy level of the first excited triplet state of the host material, making it difficult to form the main energy transfer pathway. Therefore, the explanation is omitted here. When the excited state of the host material molecule is the first excited singlet state, the energy level of the first excited singlet state of the host material molecule is higher than that of the first excited singlet state of the guest material molecule and the first excited triplet state of the guest material molecule. The excitation energy is transferred from the host material to the guest material, and the guest material molecule is in the first excited singlet state or the first excited triplet state. The guest material molecule in the first excited triplet state emits phosphorescence. The guest material molecules in the first excited singlet state emit phosphorescence through inter-system transitions to the first excited triplet state.

Please refer to FIG. 1. The first luminescent layer 104 in this embodiment increases the pathway for energy transfer from the host material to the guest material by adding the first auxiliary material. Specifically, when the excited state of the first excimer complex is the first excited triplet state, the first excited triplet state energy level of the first excimer complex is higher than the first excited triplet state energy level of the first auxiliary material molecule. The energy level of the first excited triplet state of the first auxiliary material molecule is higher than that of the first excited triplet state of the first guest material molecule, and there is a pathway for the excitation energy to be transferred from the first excimer complex to the first guest material and from the first excimer complex to the first auxiliary material and then to the first guest material. The first guest material molecule is in the first excited triplet state, and the first guest material molecule emits phosphorescence. When the excited state of the first excimer complex molecule is the first excited singlet state, the first excited singlet state energy level of the first excimer complex molecule is higher than the first excited singlet state energy level, and the first excited triplet state energy level of the first auxiliary material molecule. The first excited singlet state energy level and the first excited triplet state energy level of the first auxiliary material molecule are higher than those of the first excited singlet state of the first guest material molecule, and the first excited triplet state of the first guest material molecule. There is a pathway for the transfer of excitation energy from the first excimer complex to the first guest material, as well as from the first excimer complex to the first auxiliary material and then to the first guest material. After the energy is transferred from the first excimer complex to the first auxiliary material, the first auxiliary material molecule is in the first excited singlet state or the first excited triplet state, And the first auxiliary material molecule has a system transition from the first excited singlet state to the first excited triplet state. After receiving energy from the first excited singlet state and the first excited triplet state of the first auxiliary material molecule, the first guest material molecule is in the first excited singlet state or the first excited triplet state, and the first guest material molecule in the first excited triplet state emits phosphorescence. The first guest material molecule in the first excited singlet state emits phosphorescence through inter-system transitions to the first excited triplet state.

This embodiment increases the energy transfer pathway between the first excimer complex and the first guest material by adding the first auxiliary material. Moreover, due to the reduced energy level difference during the energy transfer process, the energy loss through the energy transfer pathway transferred through the first auxiliary material is less than the direct energy transfer between the first excimer complex and the first guest material, improving the energy transfer efficiency, Furthermore, the lifespan of the light-emitting element 101 is extended.

Preferably, the first excited singlet energy level of the first host material is higher than the first excited singlet energy level of the first auxiliary material, the first excited singlet energy level of the second host material is higher than the first excited singlet energy level of the first auxiliary material, and the first excited singlet energy level of the first auxiliary material is higher than the first excited singlet energy level of the first guest material.

The emission wavelength depends on the energy difference between the highest occupied molecular orbital (HOMO) level and the lowest unoccupied molecular orbital (LUMO) level. Therefore, the highest occupied molecular orbital level of the first auxiliary material is higher than the highest occupied molecular orbital level of the first excimer complex. The highest occupied molecular orbital energy level of the first auxiliary material is lower than the highest occupied molecular orbital energy level of the first guest material. The lowest unoccupied molecular orbital energy level of the first auxiliary material is lower than the lowest unoccupied molecular orbital energy level of the first excimer complex, and the lowest unoccupied molecular orbital energy level of the first auxiliary material is higher than the lowest unoccupied molecular orbital energy level of the first guest material. By adjusting the energy difference between the HOMO and LUMO of the first excimer complex, the first auxiliary material, and the first guest material, the peak wavelength of the emission peak of the first excimer complex, the first auxiliary material, and the first guest material can be regulated. Preferably, the highest occupied molecular orbital energy level of the first auxiliary material is higher than the highest occupied molecular orbital energy level of the first host material, the highest occupied molecular orbital energy level of the first auxiliary material is higher than the highest occupied molecular orbital energy level of the second host material, and the highest occupied molecular orbital energy level of the first auxiliary material is lower than the highest occupied molecular orbital energy level of the first guest material. The lowest unoccupied molecular orbital energy level of the first auxiliary material is lower than the lowest unoccupied molecular orbital energy level of the first host material, the lowest unoccupied molecular orbital energy level of the first auxiliary material is lower than the lowest unoccupied molecular orbital energy level of the second host material, and the lowest unoccupied molecular orbital energy level of the first auxiliary material is higher than the lowest unoccupied molecular orbital energy level of the first guest material.

In this embodiment, the second luminescent layer 105 comprises a third host material, a fourth host material, and a second guest material, and the third host material forms a second excimer complex with the fourth host material.

In this embodiment, the second luminescent layer 105 also comprises a second auxiliary material, wherein a first excited triplet state energy level of the second auxiliary material is lower than a first excited triplet state energy level of the second excimer complex, and the first excited triplet state energy level of the second auxiliary material is higher than a first excited triplet state energy level of the second guest material.

When the second luminescent layer 105 also comprises the second auxiliary material, the luminescent principle of the second luminescent layer 105 is similar to that of the first luminescent layer 104, and will not be repeated here. The volume proportion range and selection reason of the third main body material, the fourth main body material, the second auxiliary material, and the second guest material in the second luminescent layer 105 are related to the first main body material and the second main body material in the first luminescent layer 104 The volume proportion range and selection reasons of the first auxiliary material and the first guest material in the first luminescent layer 104 are the same or similar, and will not be repeated here. When the second auxiliary material is added to the second luminescent layer 105, the energy transfer pathway between the second excimer complex and the second guest material is increased, and due to the reduced energy level difference during the energy transfer process, the energy loss through the energy transfer pathway transferred through the second auxiliary material is less than the direct energy transfer between the second excimer complex and the second guest material, improving the energy transfer efficiency. Therefore, the luminous efficiency of the light-emitting element 101 is further improved and the service life of the light-emitting element 101 is extended.

When the second luminescent layer 105 comprises the second auxiliary material, it is preferred that the highest occupied molecular orbital energy level of the second auxiliary material is higher than the highest occupied molecular orbital energy level of the third main body material, and the highest occupied molecular orbital energy level of the second auxiliary material is higher than the highest occupied molecular orbital energy level of the fourth main body material. The highest occupied molecular orbital energy level of the second auxiliary material is lower than the highest occupied molecular orbital energy level of the second guest material.

Preferably, the lowest unoccupied molecular orbital energy level of the second auxiliary material is lower than the lowest unoccupied molecular orbital energy level of the third host material, the lowest unoccupied molecular orbital energy level of the second auxiliary material is lower than the lowest unoccupied molecular orbital energy level of the fourth host material, and the lowest unoccupied molecular orbital energy level of the second auxiliary material is higher than the lowest unoccupied molecular orbital energy level of the second guest material.

Preferably, the first excited singlet energy level of the third host material is higher than the first excited singlet energy level of the second auxiliary material, the first excited singlet energy level of the fourth host material is higher than the first excited singlet energy level of the second auxiliary material, and the first excited singlet energy level of the second auxiliary material is higher than the first excited singlet energy level of the second guest material.

The first guest material and the second guest material can be phosphorescent compounds, and the first guest material, the first auxiliary material, the second guest material, and the second auxiliary material are selected from one of the organic metal compounds of platinum, iridium, or osmium, respectively. By setting the first guest material, the first auxiliary material, the second guest material, and the second auxiliary material as organic metal compounds, the first auxiliary material and the second auxiliary material respectively improve the π-π stacking between molecules of the first guest material and the π-π stacking between molecules of the second guest material, thereby enhancing the first guest material in the first luminescent layer 104 The dispersion of the second guest material in the second luminescent layer 105 reduces the probability of collisions between the first guest materials in the first excited triplet state, as well as the probability of collisions between the second guest materials in the first excited triplet state, reducing damage to the guest material caused by collisions, and extending the lifespan of the light-emitting element 101. At the same time, the increase in molecules of the first guest material in the first excited triplet state that releases energy in the form of luminescence, as well as molecules of the second guest material in the first excited triplet state that releases energy in the form of luminescence, also improves the luminous efficiency of the light-emitting element 101 and prolongs its lifespan.

Preferably, considering the differences in the first excited triplet energy levels between metal-organic compounds formed by different types of metals, when the first guest material is an organic metal compound of platinum or iridium, the first auxiliary material is an organic metal compound of platinum or iridium that is different from the first guest material. The first guest material is an organic metal compound of osmium, and the first auxiliary material is an organic metal compound of osmium. When the second luminescent layer 105 comprises the second auxiliary material, and the second guest material is an organic metal compound of platinum or iridium, the second auxiliary material is an organic metal compound of platinum or iridium that is different from the second guest material. The second guest material is an organic metal compound of osmium, and the second auxiliary material is an organic metal compound of osmium. The selection of the first object material and the second object material can be the same or different, and the selection of the first auxiliary material and the second auxiliary material can be the same or different.

Specifically, the first guest material and the second guest material can be selected from any or more combinations of the following compounds, and the first auxiliary material and the second auxiliary material can be selected from any or more combinations of the following compounds:

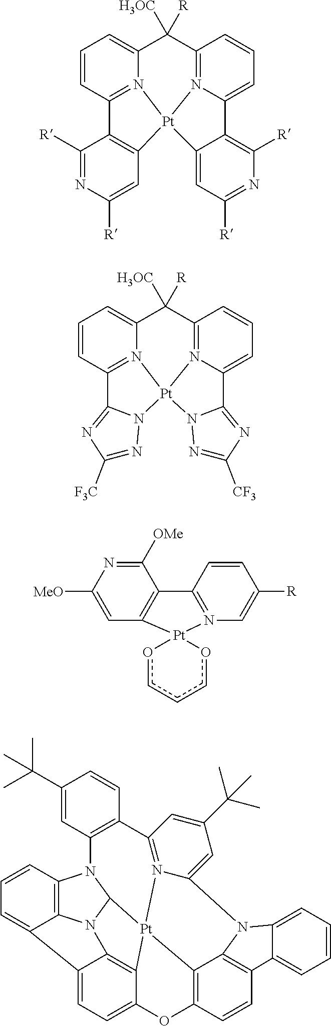

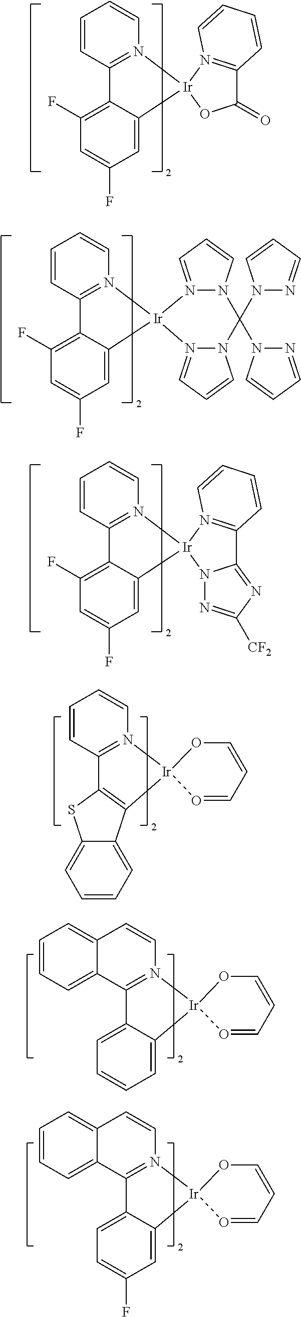

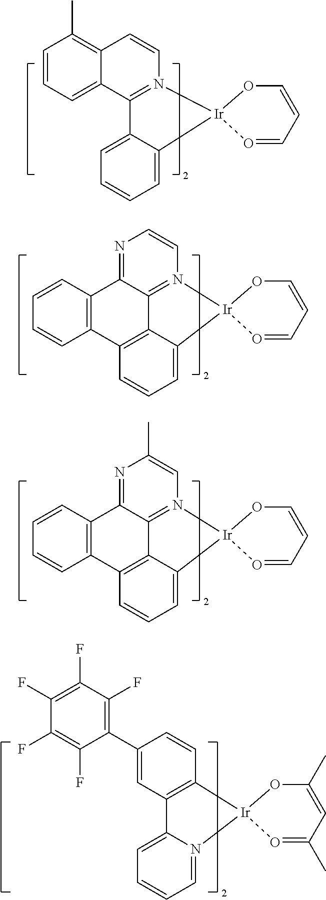

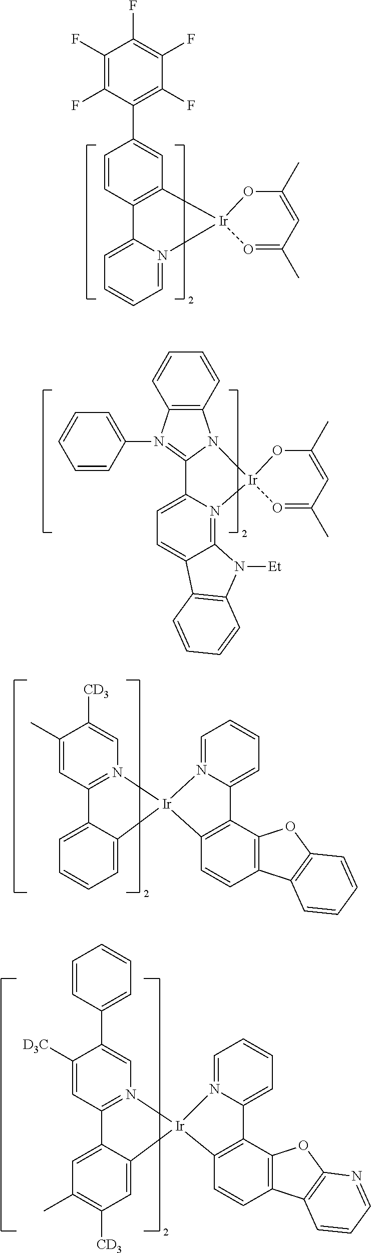

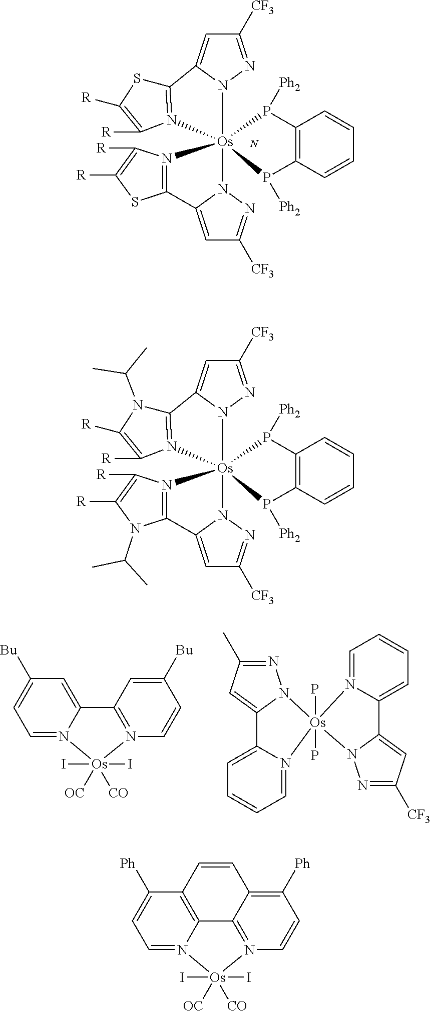

This embodiment first forms a first excimer complex by combining the first host material with the second host material. The first excimer complex is formed by the interaction between the first host material molecule in the excited state and the second host material molecule in the excited state. The first host material can be one of the hole transport organic compounds or electron transport compounds. The second host material can be a hole transport organic compound or another type of electron transport compound, for example, the first host material is a hole transport organic compound, and the second host material is an electron transport compound. Similarly, the third host material can be one of the hole transport organic compounds or electron transport properties compounds, and the fourth host material can be another of the hole transport organic compounds or electron transport properties compounds. For example, the third host material is a hole transport organic compound, and the fourth host material is an electron transport property compound.

Among them, compounds with hole transport properties include aromatic amines or carbazole compounds, and compounds with electron transport properties include heteroaromatic compounds.

In some embodiments, the ratio of the mobility of the first main body material to the mobility of the second main body material is 1:1 to 21:1, and the ratio of the mobility of the third main body material to the mobility of the fourth main body material is 1:1 to 21:1. The first and third main body materials are materials with hole transfer properties, and their mobility is hole mobility. The second and fourth main body materials are materials with electron transfer properties, and their mobility is electron mobility.

Specifically, the migration rate of the first and third main body materials is 6.4*10\hat{ }(−8)[m²/(V·s)] to 1.93*10\hat{ }(−7)[m²/(V·s)], and preferably, the migration rate of the first and third main body materials is 1.29*10\hat{ }(−7)[m²/(V·s)] to 1.93*10\hat{ }(−7)[m²/(V·s)]. More preferably, the migration rate of the first and third main body materials is 1.61*10\hat{ }(−7)[m²/(V·s)].

The migration rate of the second and fourth main body materials is 6.4*10\hat{ }(−8)[m²/(V·s)] to 1.93*10\hat{ }(−7)[m²/(V·s)], preferably 6.4*10\hat{ }(−8)[m²/(V·s)] to 9.6*10\hat{ }(−8) [m²/(V·s)], and more preferably, the migration rate of the second and fourth main body materials is 8*10\hat{ }(−8)[m²/(V·s)].

When the mobility of the first main body material and the third main body material is within the above range, especially 1.61*10\hat{ }(−7)[m²/(V·s)], the mobility of the second main body material and the fourth main body material is within the above range, especially 8*10\hat{ }(−8)[m²/(V·s)], the first luminescent layer 104 and the second luminescent layer 105 are used to generate the first excimer complex The hole and electron matching effect of the second excimer complex is the best, which is most conducive to improving the luminous efficiency of the light-emitting element 101.

In some embodiments, the doping ratio of the first main body material to the second main body material, as well as the doping ratio of the third main body material to the fourth main body material, is 5:5 to 7:3, such as 5.5:4.5, 5.9:4.1, 6:4, 6.5:3.5, 6.8:3.2, 7:3, etc. Preferably, the doping ratio of the first main body material to the second main body material, as well as the doping ratio of the third main body material to the fourth main body material, are 7:3, 6:4, or 5:5. Most preferably, the doping ratio of the first main body material to the second main body material, as well as the doping ratio of the third main body material to the fourth main body material, are all 7:3. The doping ratio of the first main body material to the second main body material refers to the ratio of the volume occupied by the first main body material in the first luminescent layer 104 to the volume occupied by the second main body material in the first luminescent layer 104, and the doping ratio of the third main body material to the fourth main body material. The ratio of the volume occupied by the third main body material in the second luminescent layer 105 to the volume occupied by the fourth main body material in the second luminescent layer 105.

The first main body material, the second main body material, the third main body material, and the fourth main body material can be independently selected from bis [2-(diphenylphosphine) phenyl] ether oxide (DPEPO), 4,4′-bis (carbazol-9 yl) biphenyl (CBP), 1,3-bis (carbazol-9 yl) benzene (mCP), 2,8-bis (diphenylphosphoryl) dibenzo [b,d] furan (PPF), 4,4′,4″-tri (carbazol-9 yl) triphenylamine (TCTA), respectively 1,3,5-tris (1-phenyl-1H-benzo [d] imidazol-2-yl) benzene (TPBi), tri (8-hydroxyquinoline) aluminum (Alq3), 4,4′-bis (N-carbazolyl)-1,1′-biphenyl (CBP), poly (N-vinylcarbazole) (PVK), 9,10-di (naphthalen-2-yl) anthracene (ADN), 4,4′,4″-tri (carbazol-9 yl)-triphenylamine (TCTA), 2-tert-butyl-9,10-di (naphthalen-2-yl) anthracene (TBADN), and styrene Diarylidene group (DSA), 4,4′-bis (9-carbazolyl)-2,2′-dimethylbiphenyl (CDBP) 2-methyl-9,10-bis (naphthalen-2-yl) anthracene (MADN), hexaphenylcyclotriphosphazene (CP1), 1,4-bis (triphenylsilyl) benzene (UGH2), hexaphenylcyclotrisiloxane (DPSiO3), octaphenylcyclotetrasiloxane (DPSiO4), etc.

Specifically, the first main body material, the second main body material, the third main body material, and the fourth main body material can be selected from any or more combinations of the following compounds:

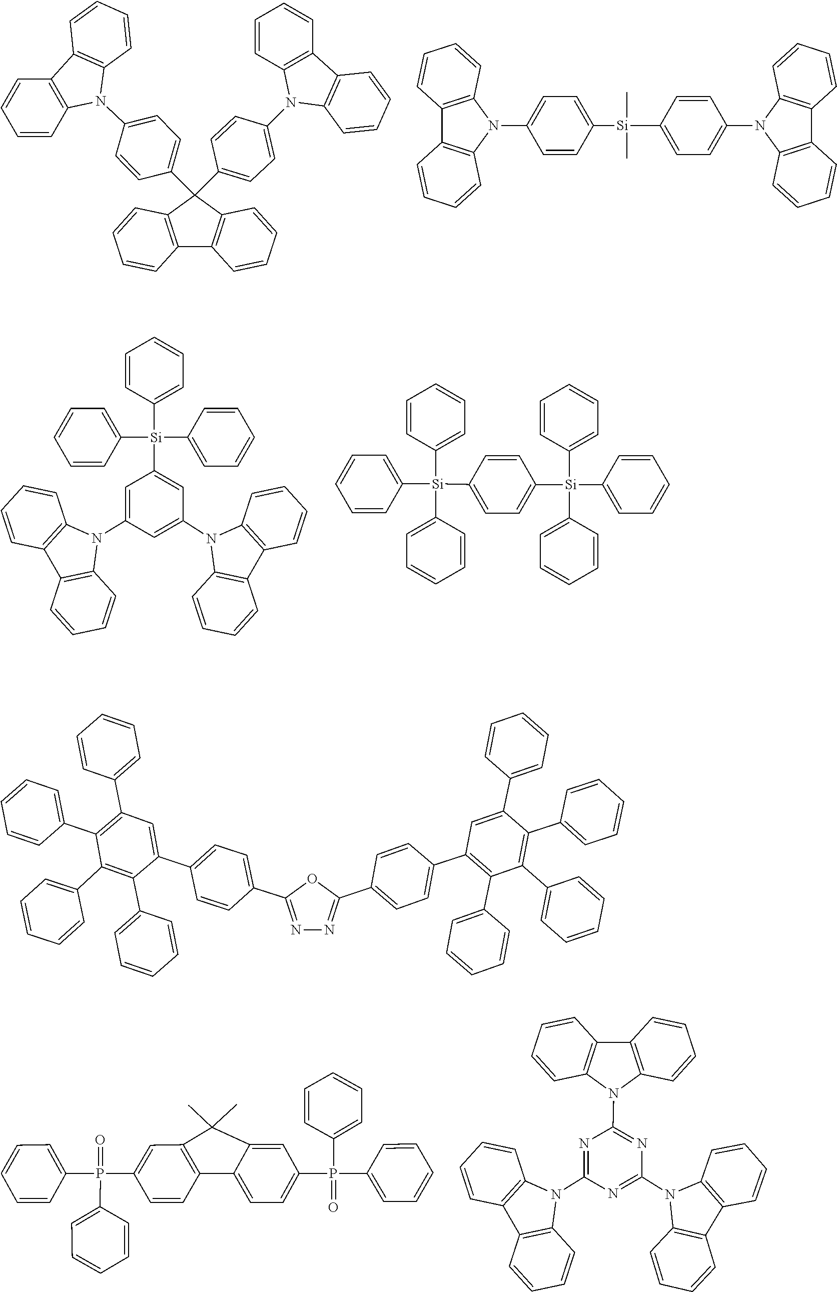

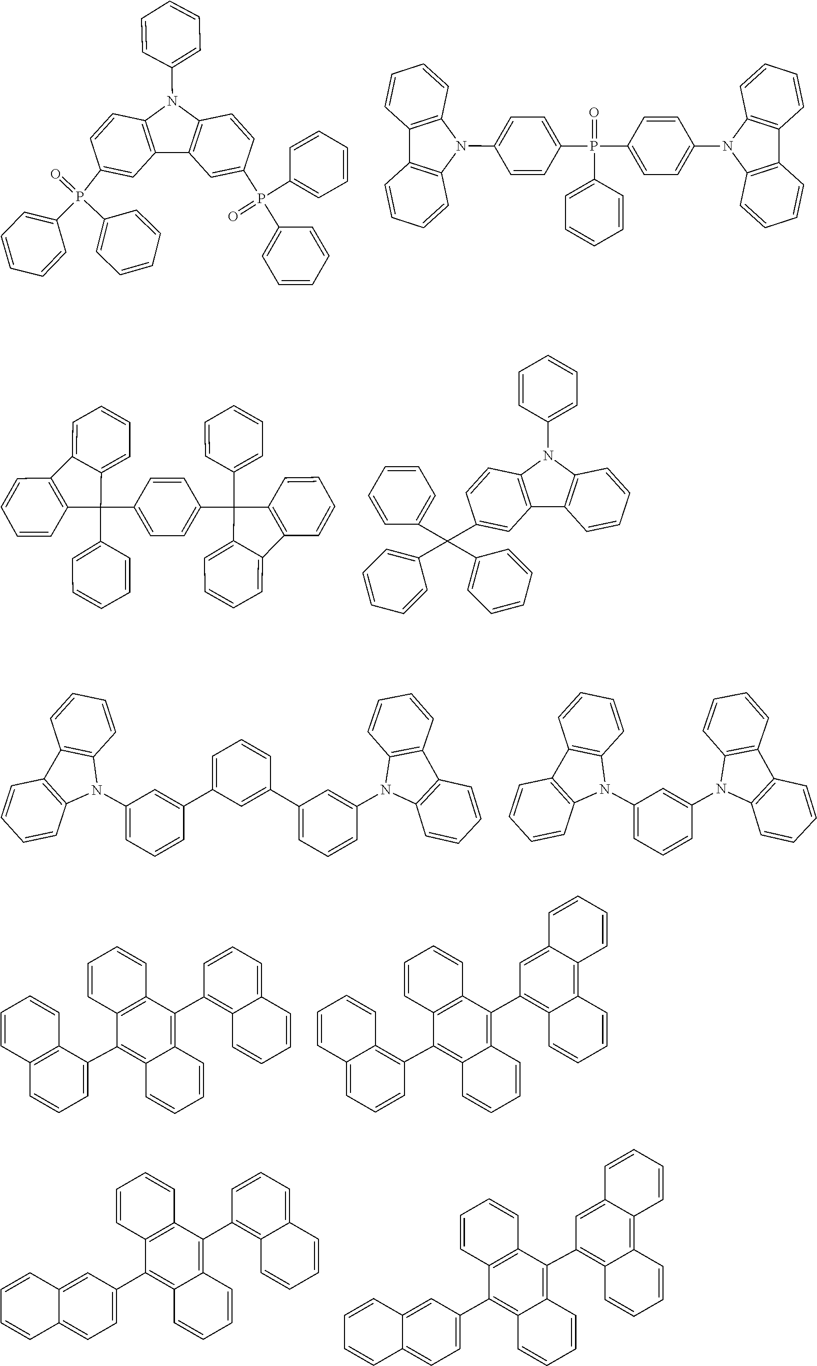

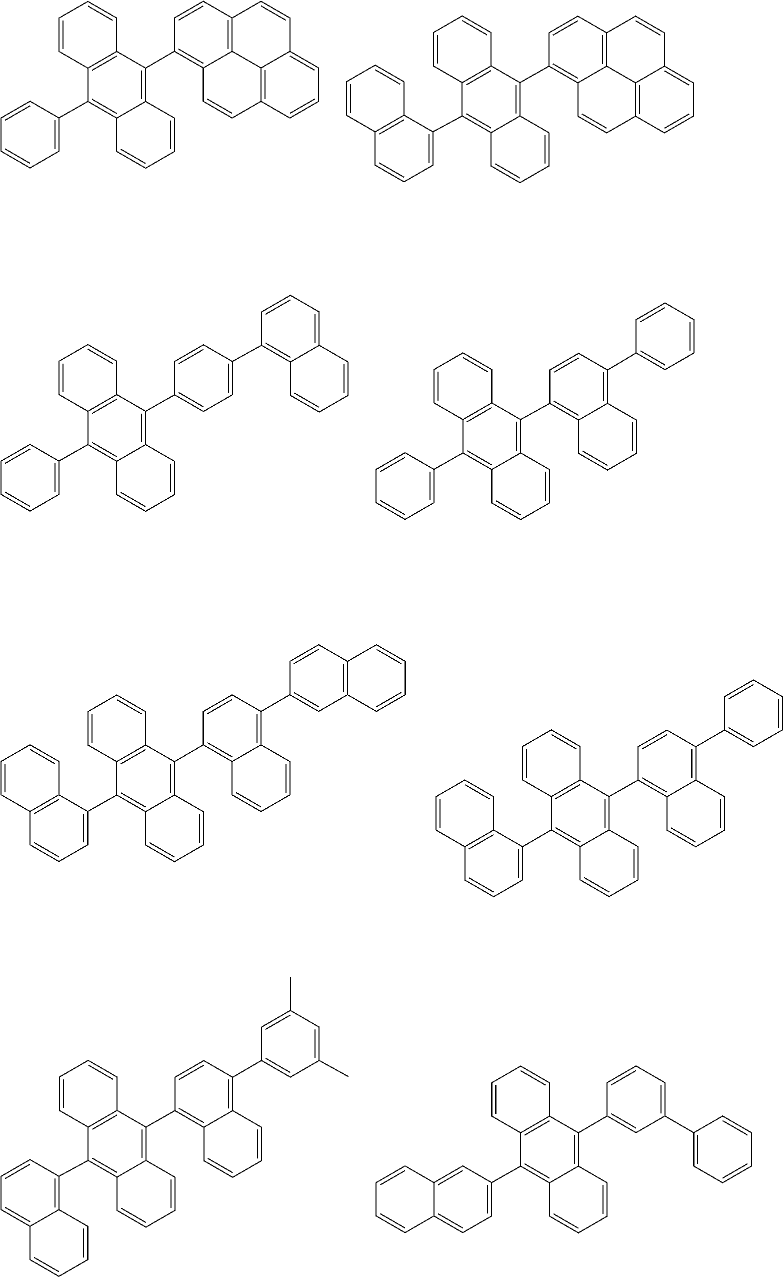

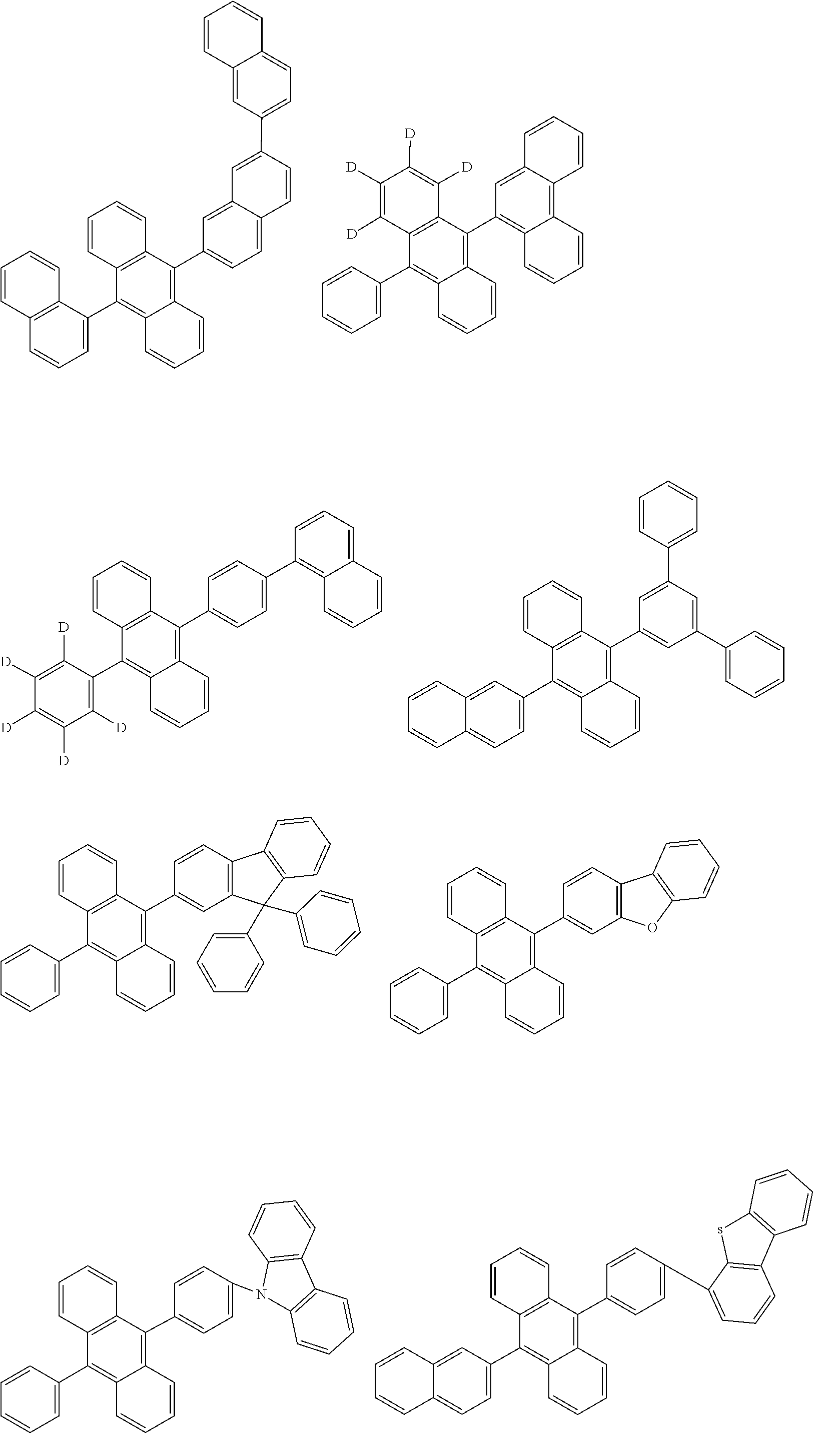

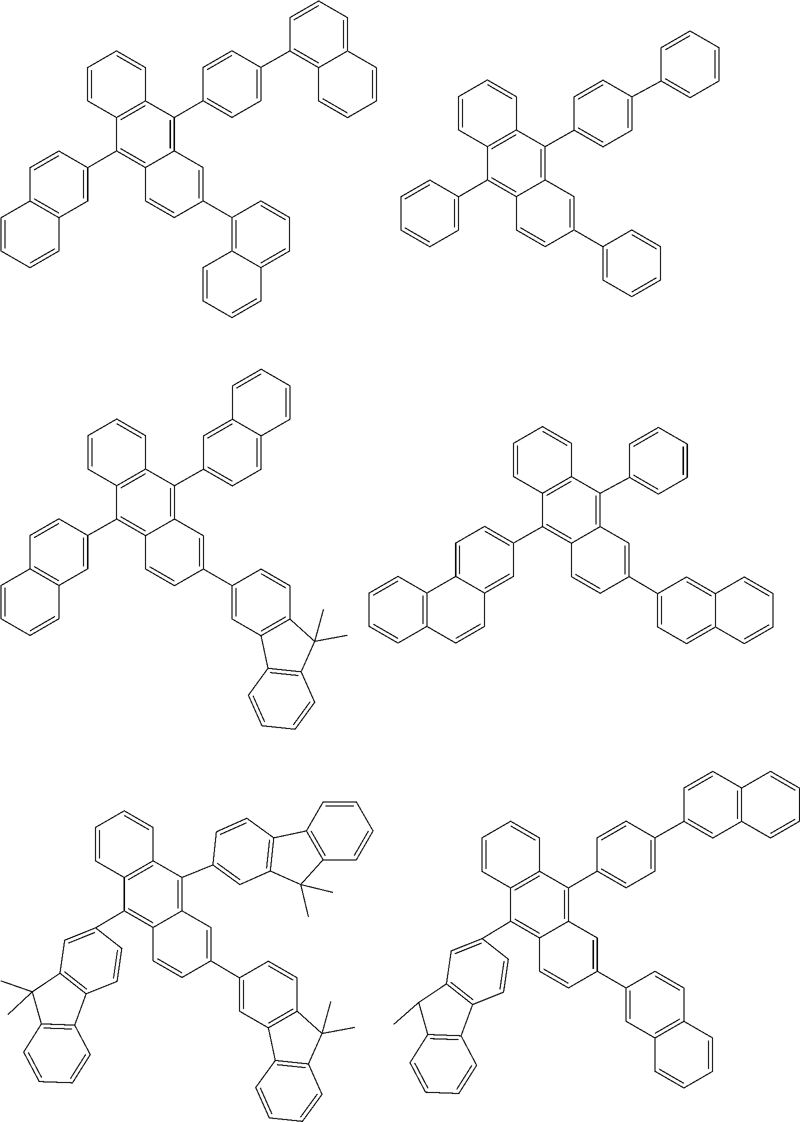

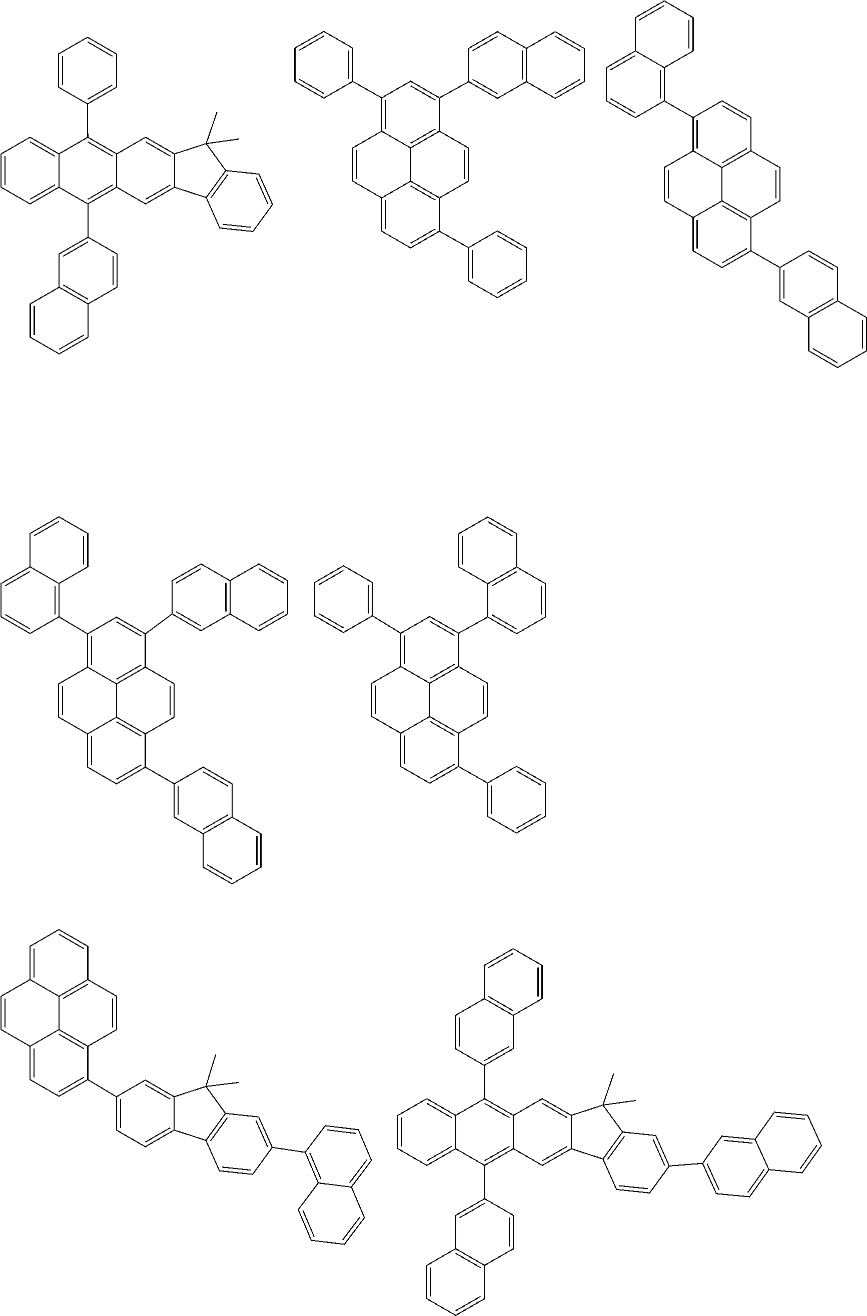

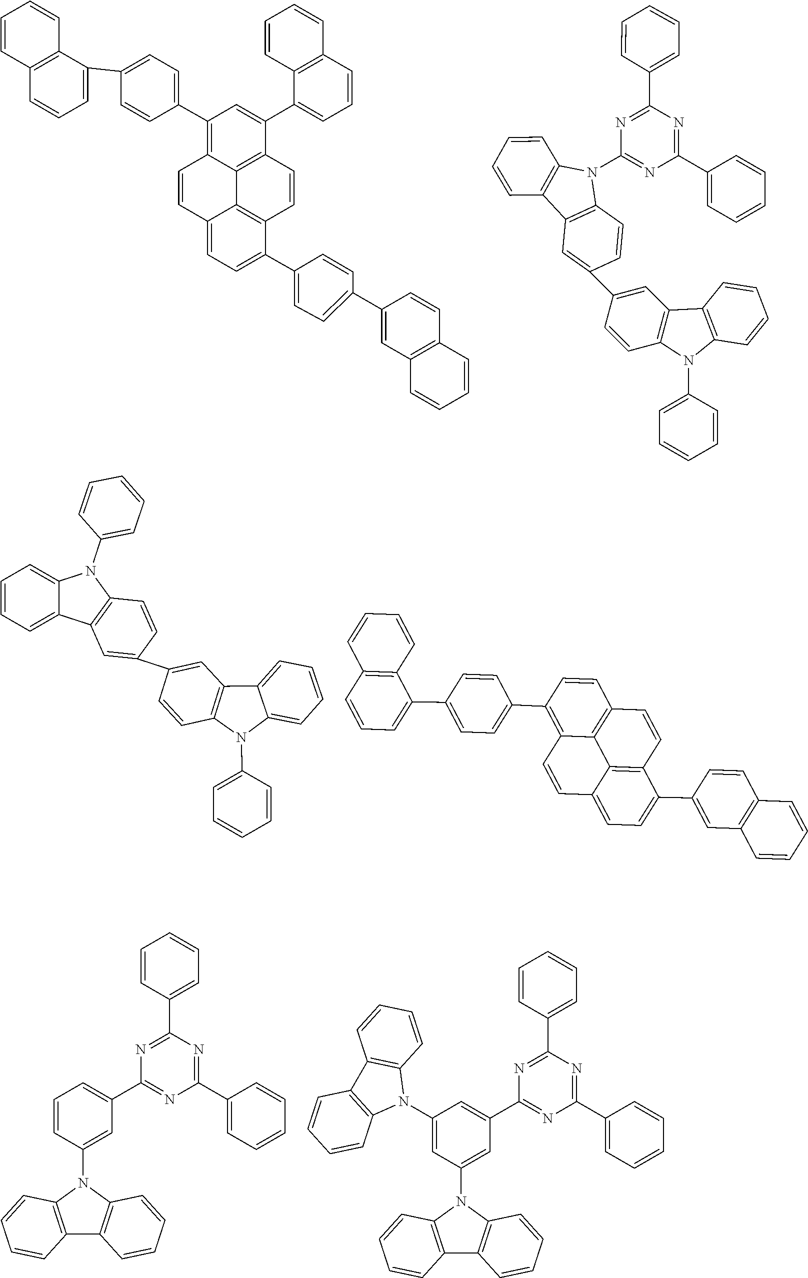

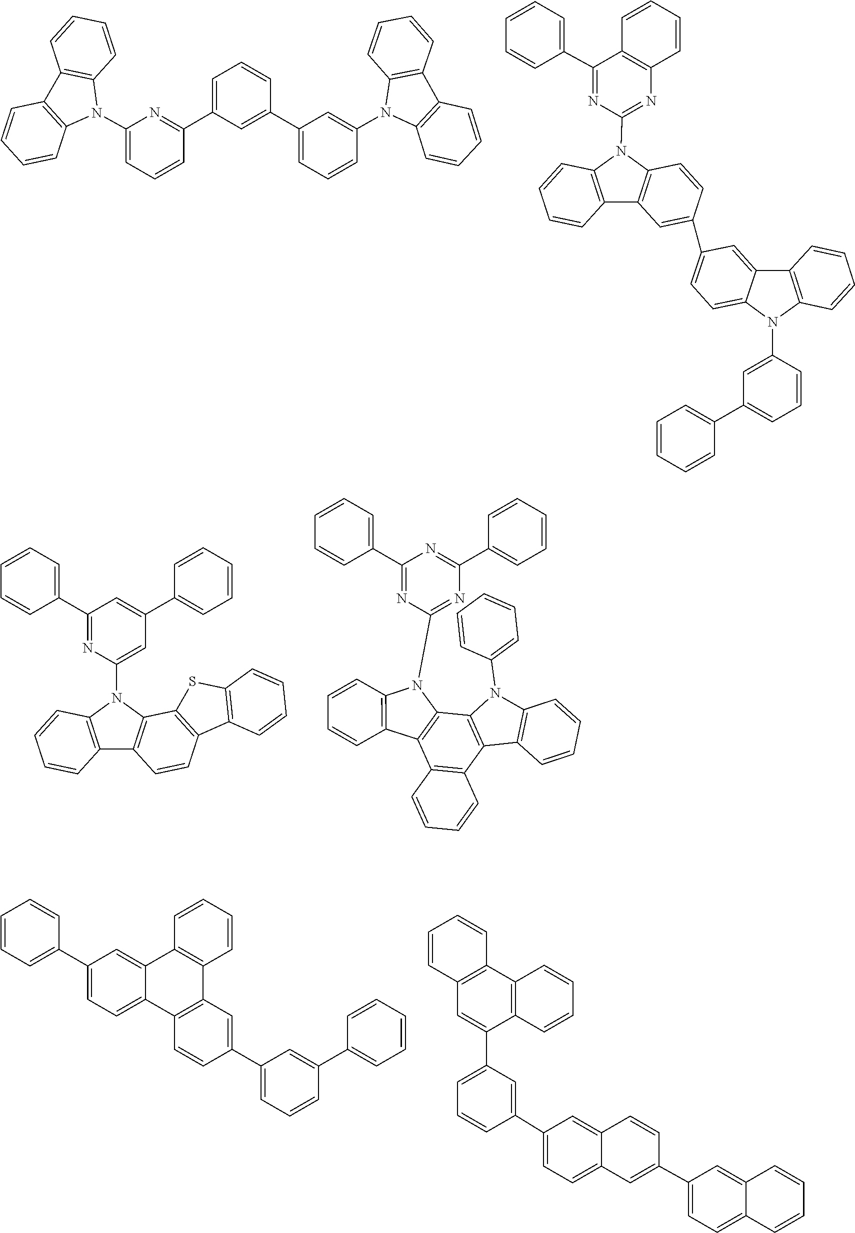

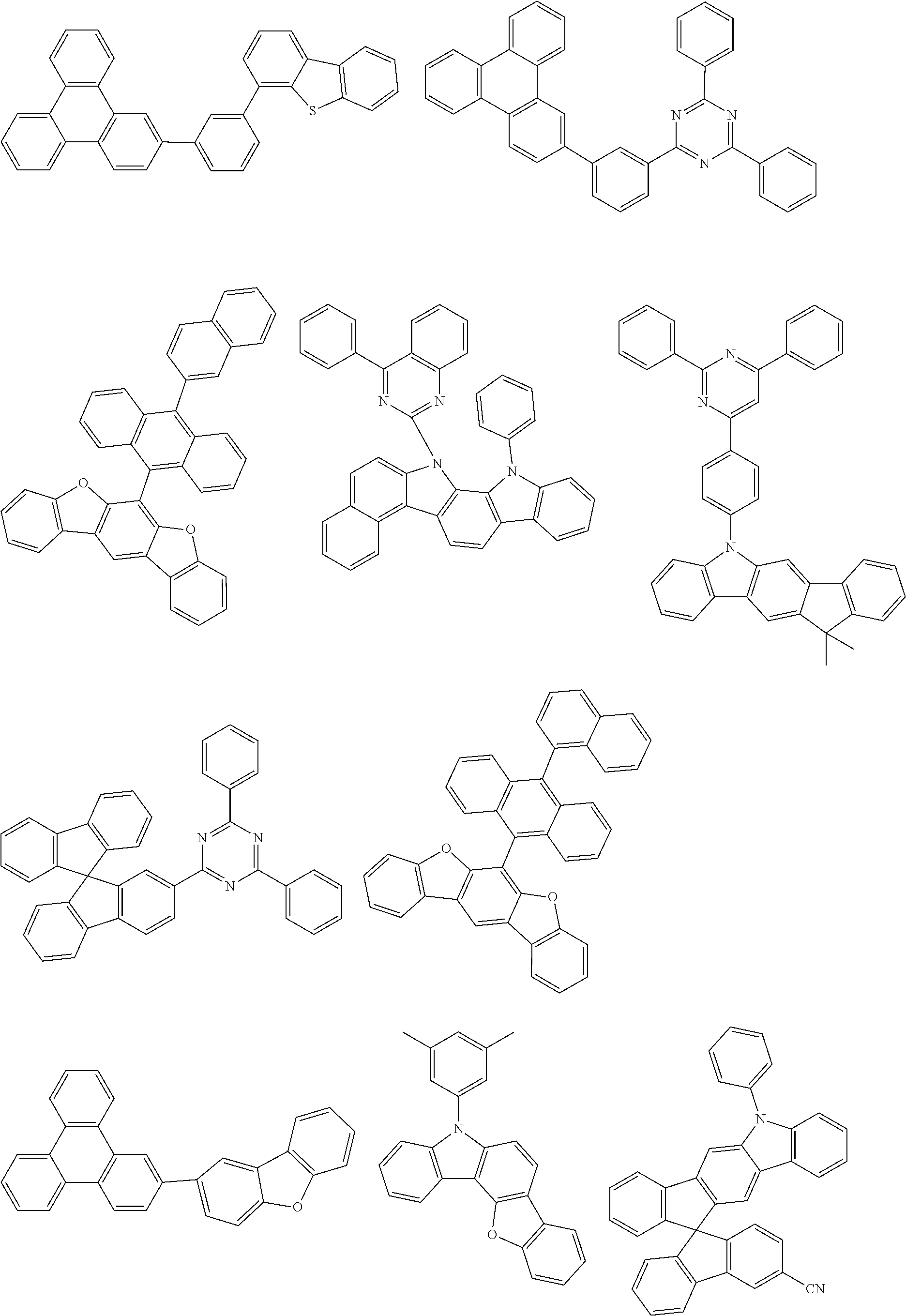

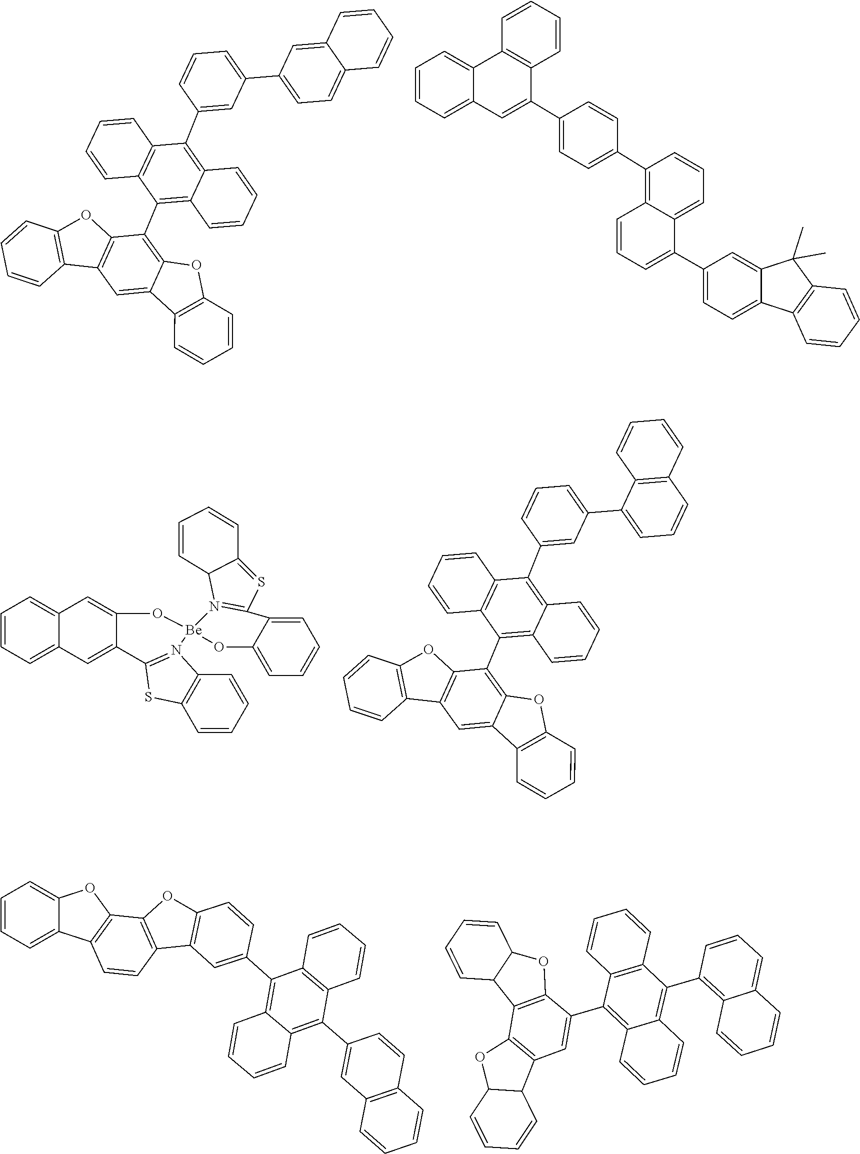

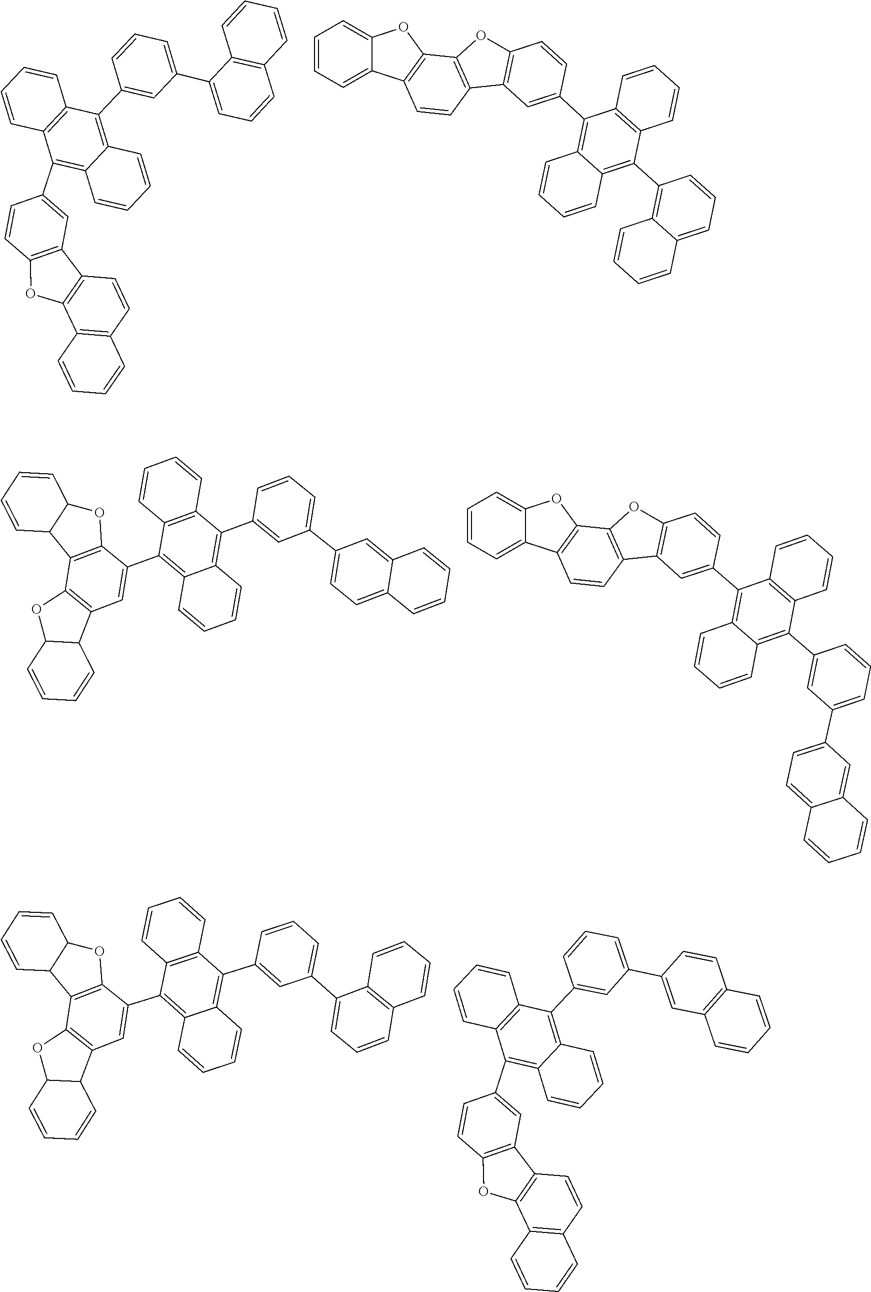

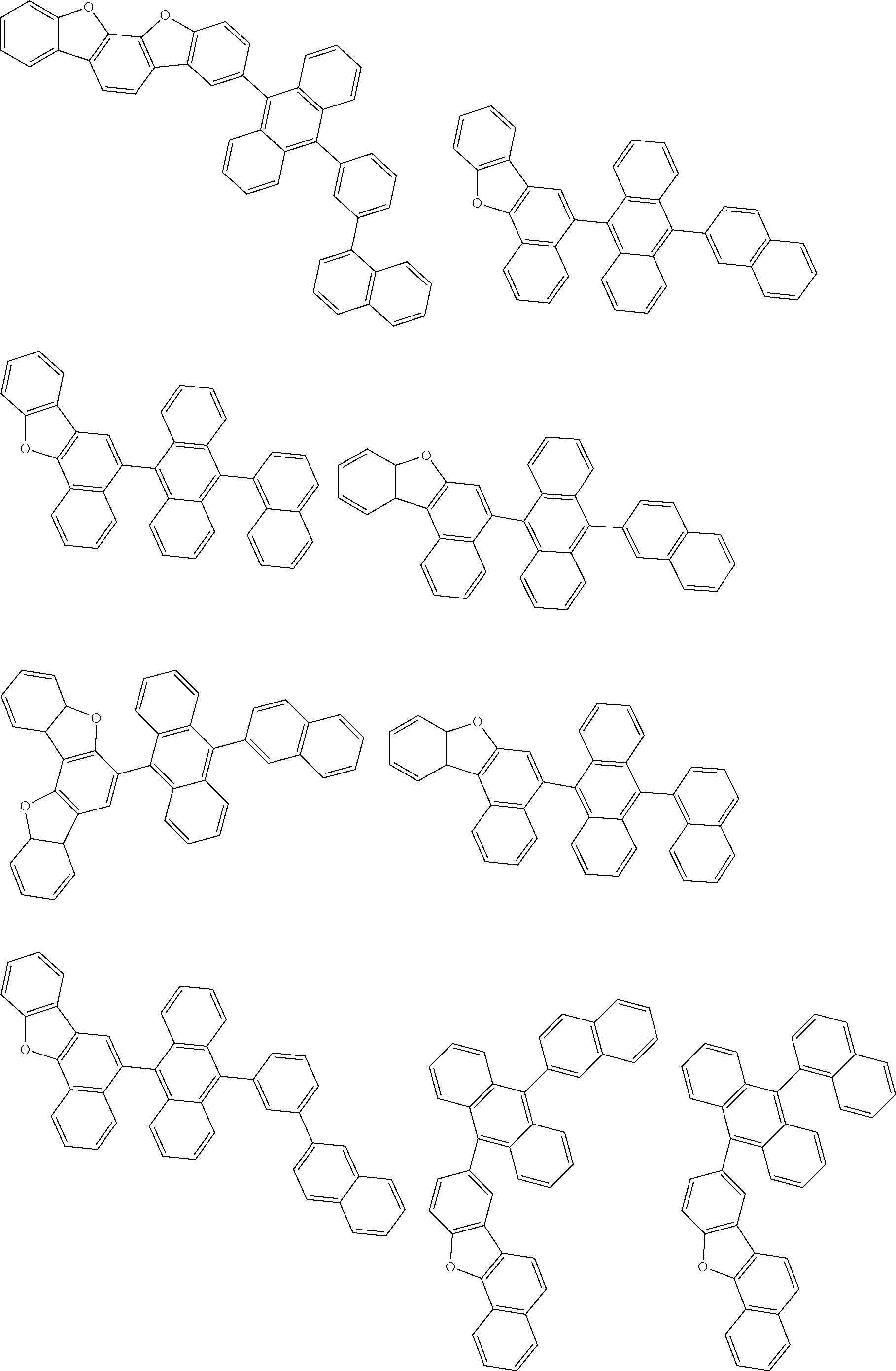

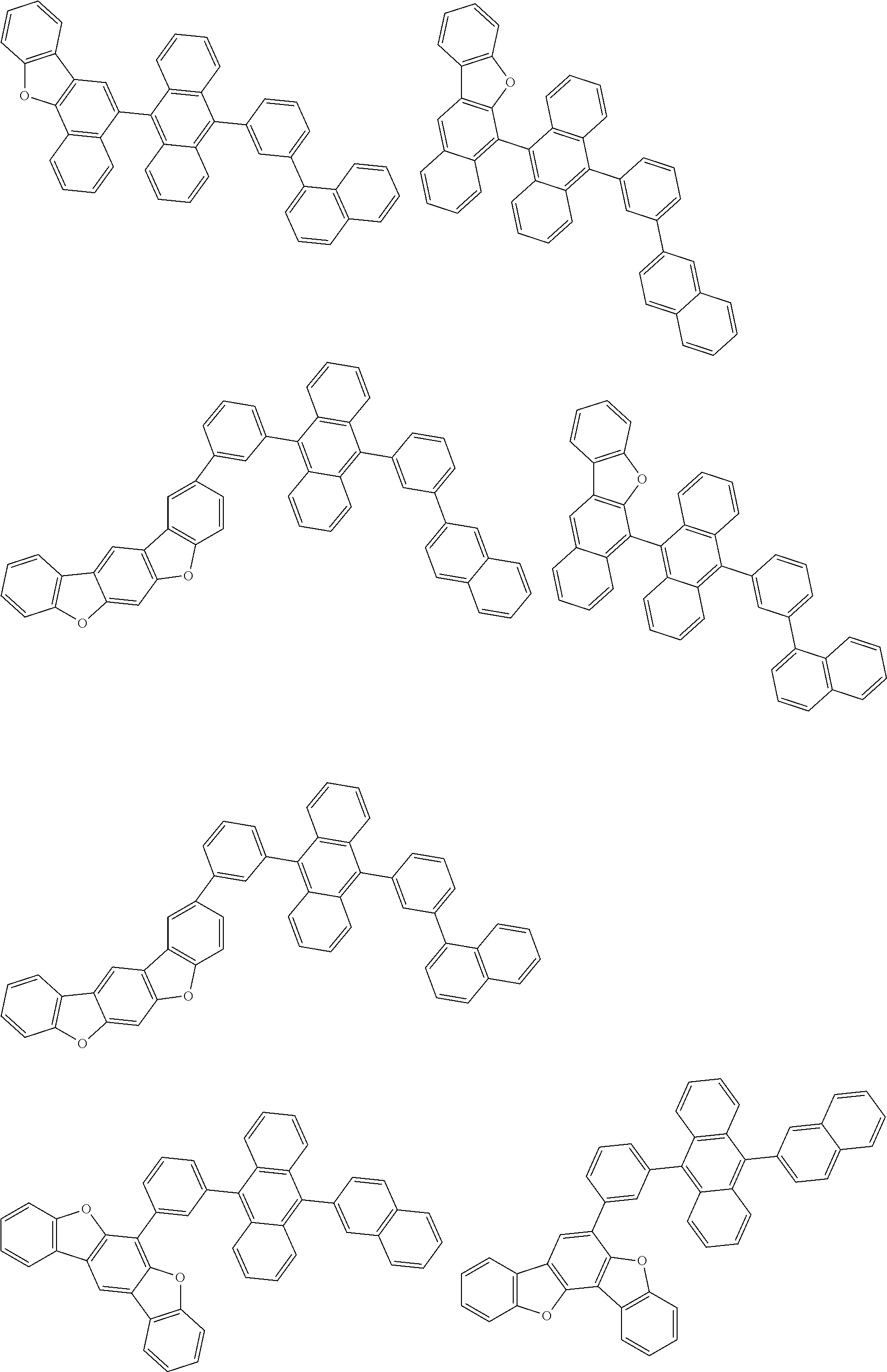

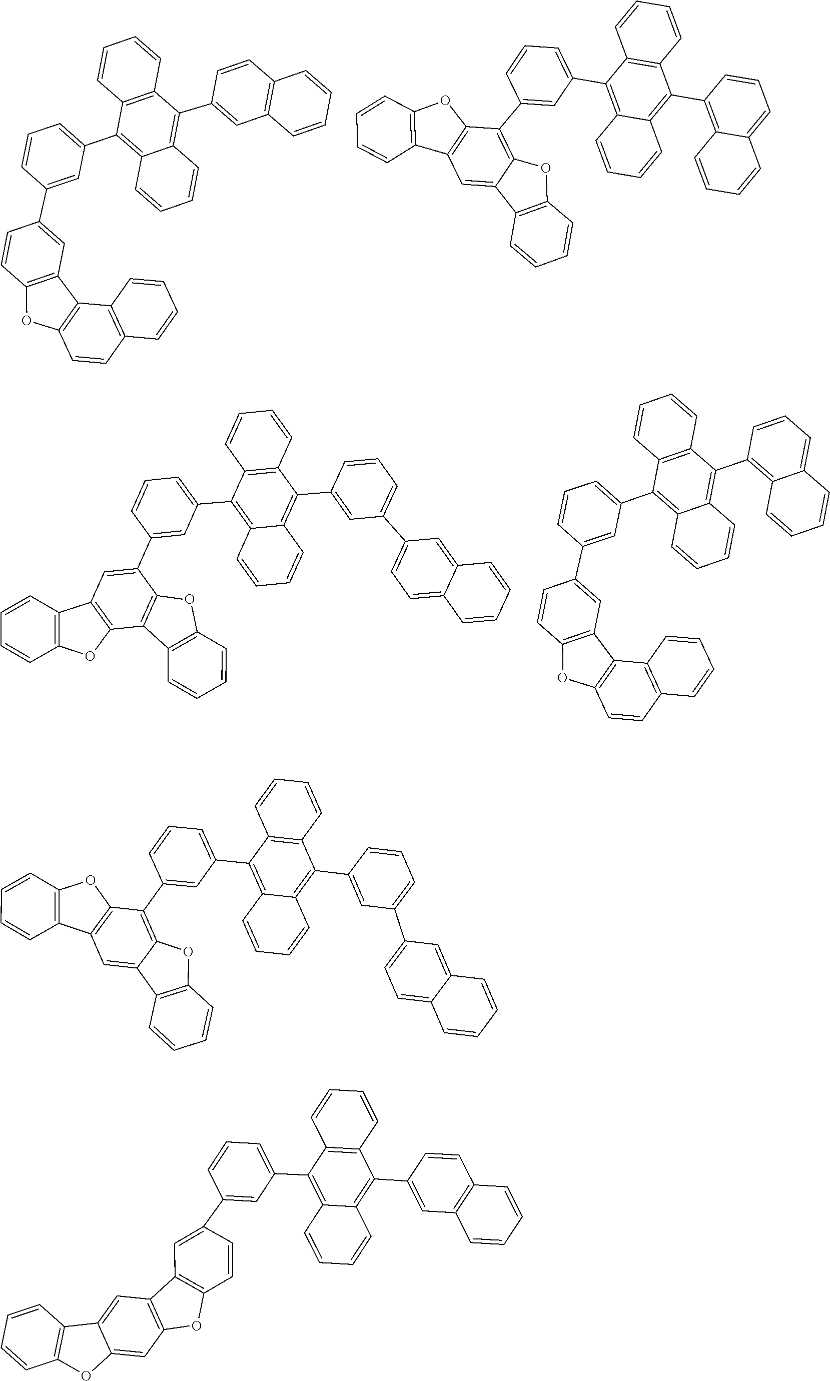

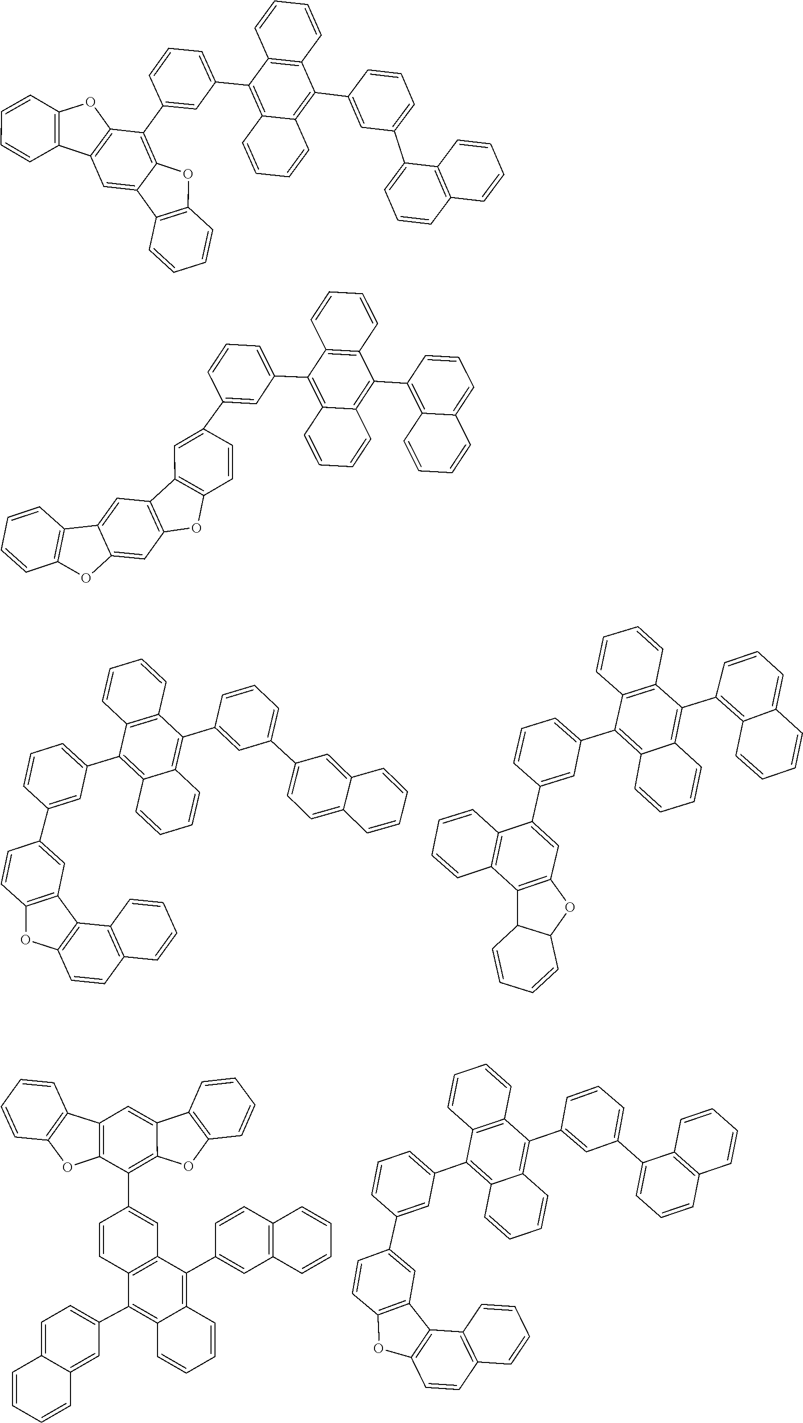

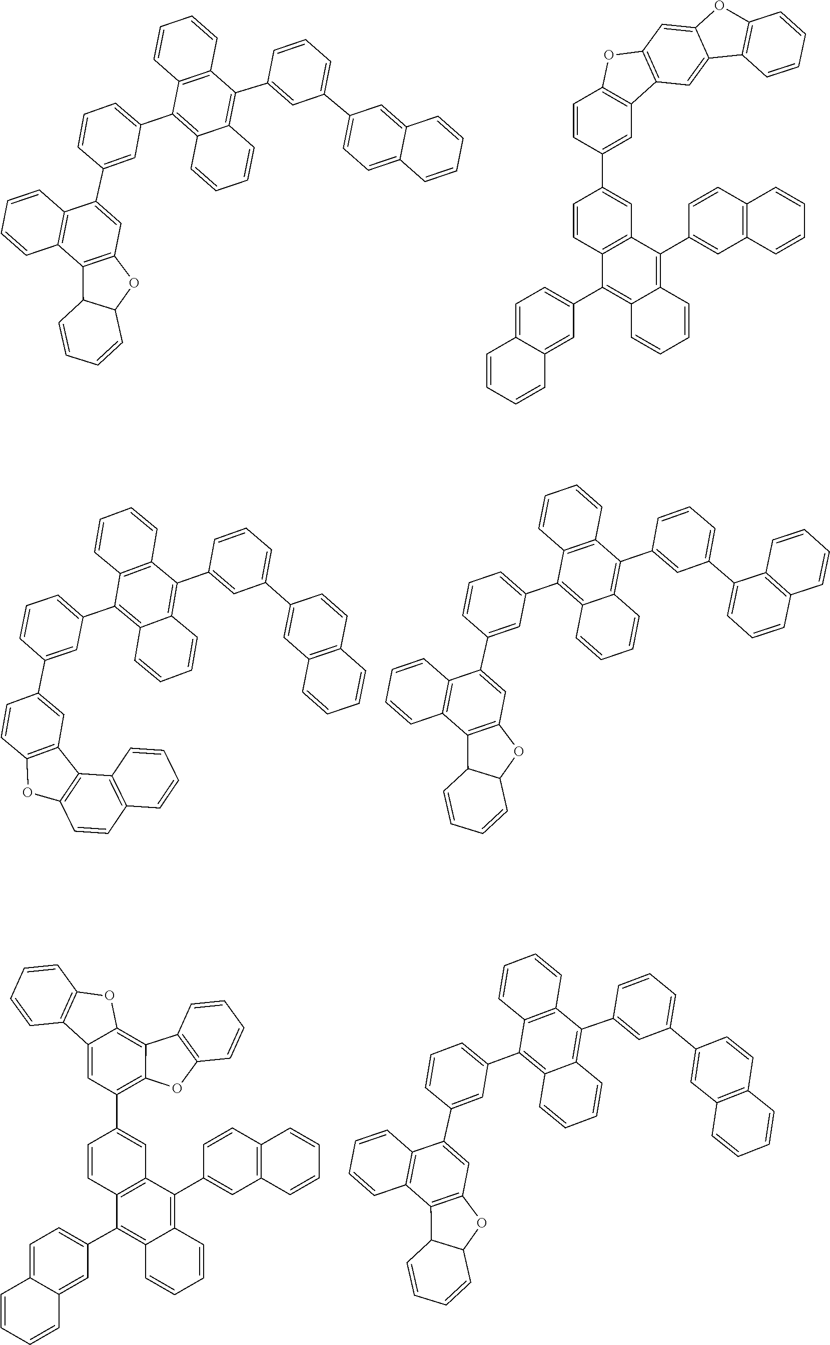

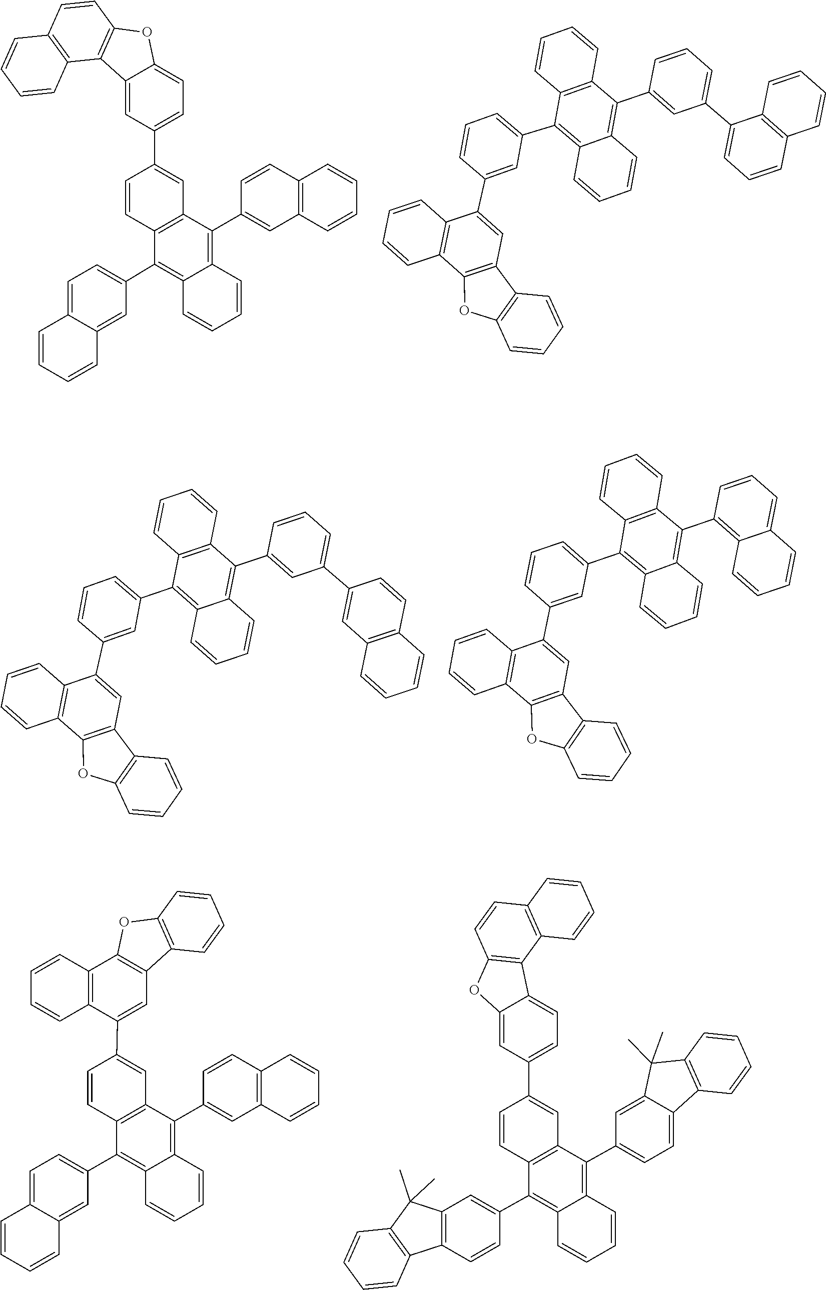

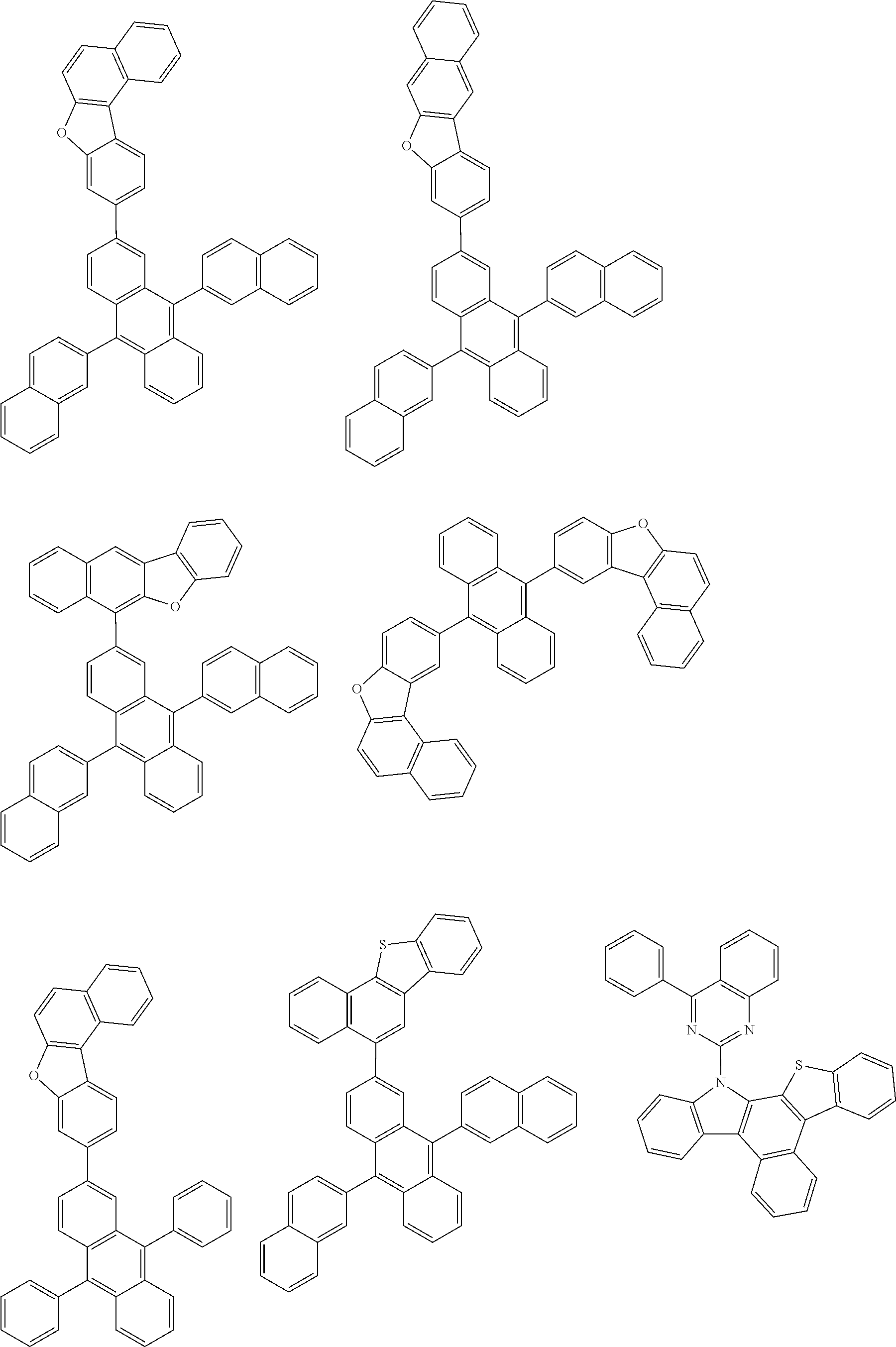

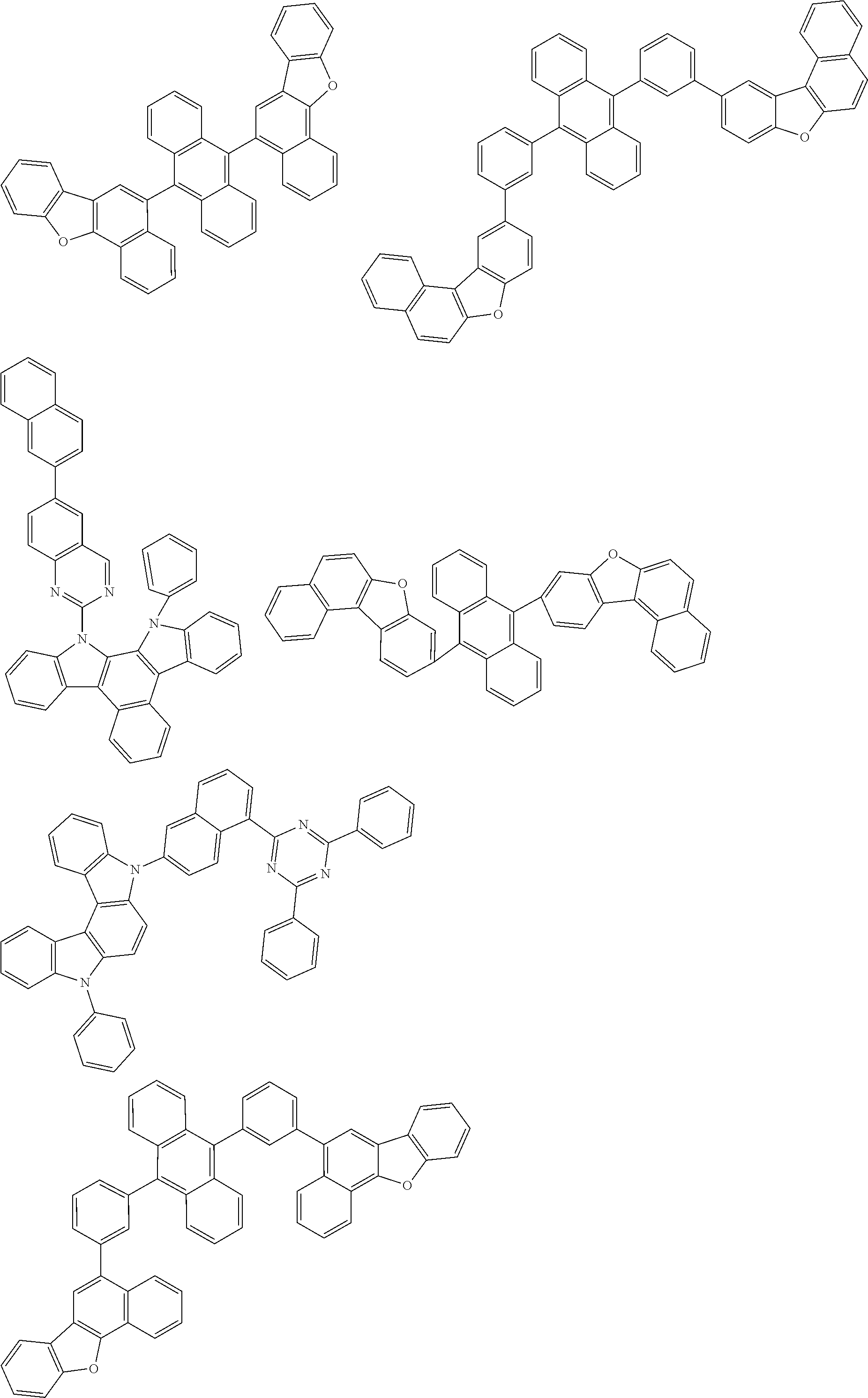

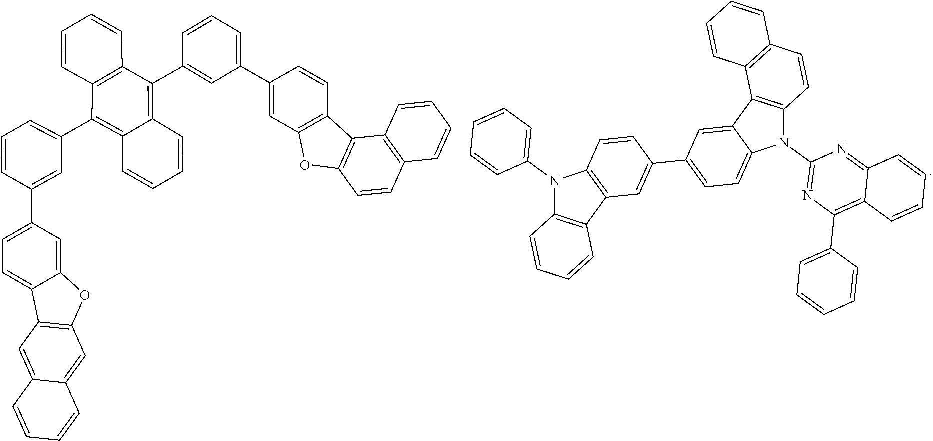

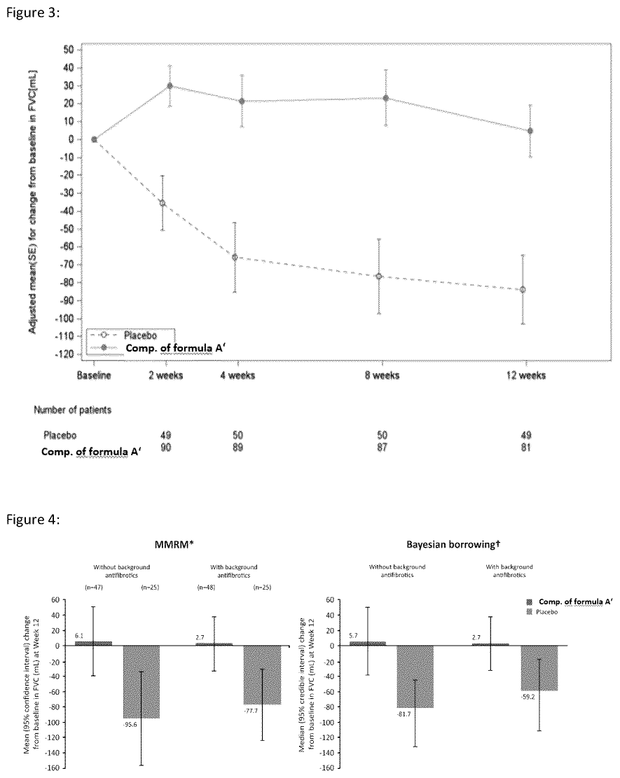

Please refer to FIGS. 2 to 3. The first light-emitting unit 101A comprises a first electron barrier layer 106 and a first hole transport layer 107 located on the side of the first electron barrier layer 106 near the first electrode 102. The first electron barrier layer 106 is in direct contact with the first light-emitting layer 104, and the first electron barrier layer 106 is in direct contact with the first hole transport layer 107.

The first electron barrier layer 106 comprises a first electron barrier material, wherein a difference between the highest occupied molecular orbital energy level of the first electron barrier material and the highest occupied molecular orbital energy level of the first excimer complex is less than 0.3 eV (such as 0.28 eV, 0.25 eV, 0.22 eV, 0.20 eV, 0.18 eV, 0.15 eV, 0.10 eV, 0.05 eV, etc.). A difference between the highest occupied molecular orbital energy level of the first hole transport material and the highest occupied molecular orbital energy level of the first electron barrier material is less than 0.3 eV (such as 0.28 eV, 0.25 eV, 0.22 eV, 0.20 eV, 0.18 eV, 0.15 eV, 0.10 eV, 0.05 eV, etc.), and the first electron barrier layer 106 plays a transitional role between the first hole transport layer 107 and the first luminescent layer 104, It is advantageous for holes to be transmitted from the first hole transport layer 107 to the first luminescent layer 104 through the first electron barrier layer 106, thereby reducing the driving voltage of the light-emitting element 101.

A difference between the lowest unoccupied molecular orbital energy level of the first electron barrier material and the lowest unoccupied molecular orbital energy level of the first excimer complex is greater than 0.05 eV (such as 0.06 eV, 0.08 eV, 0.10 eV, 0.12 eV, 0.15 eV, etc.), and a difference between the lowest unoccupied molecular orbital energy level of the first hole transport material and the lowest unoccupied molecular orbital energy level of the first electron barrier material is greater than 0.05 eV, Beneficial to the blocking effect of the first electron barrier layer 106 on electrons from the first luminescent layer 104 to the first electron barrier layer 106, reducing the number of electrons passing from the first luminescent layer 104 to the first hole transport layer 107 through the first electron barrier layer 106, thereby improving the luminous efficiency of the luminescent device.

A difference between the first excited triplet state energy level of the first electron barrier layer 106 and the first excited triplet state energy level of the first exciton complex is greater than 0.15 eV (such as 0.16 eV, 0.18 eV, 0.20 eV, 0.22 eV, 0.25 eV, etc.), which is conducive to energy transfer from the first electron transport layer to the first exciton complex and reduces the driving voltage of the light-emitting element 101.

Please refer to FIG. 4, the first emitting unit 101A also comprises a first hole transport layer 107 located on the side of the first emitting layer 104 near the first electrode 102, which is in direct contact with the first emitting layer 104.

Due to the need for a fine mask plate for the preparation of the first electron barrier layer 106, the cost of the fine mask plate is expensive and the related components of the fine mask plate are frequently replaced, resulting in high preparation costs for the first electron barrier layer 106. By direct contact between the first hole transport layer 107 and the first light-emitting layer 104, the first electron barrier layer 106 is omitted between the first hole transport layer 107 and the first light-emitting layer 104, which saves the fine mask required for the preparation of the first electron barrier layer 106 and significantly reduces the manufacturing cost of the light-emitting element 101.

At the same time, omitting the original first electron barrier layer 106 will result in a lack of transition between the first hole transport layer 107 and the first light-emitting layer 104. The difference in the highest occupied molecular orbital energy level between the first hole transport material and the first excimer complex is too large, and the driving voltage of the light-emitting element 101 increases too much. The power consumption of the light-emitting element 101 increases too much, affecting the product quality of the light-emitting element 101. The inventor found through research that a difference between the highest occupied molecular orbital energy level of the first hole transport material and the highest occupied molecular orbital energy level of the first excimer complex can be controlled to be less than 0.4 eV. The driving voltage increase of the light-emitting element 101 is not significant, and at the same time, the manufacturing cost of the light-emitting element 101 is reduced.

Omitting the original first electron barrier layer 106 will result in a lack of transition between the first hole transport layer 107 and the first luminescent layer 104. The difference in the lowest unoccupied molecular orbital energy levels between the first hole transport material and the first excimer complex is too small, making it easier for electrons to pass from the first luminescent layer 104 to the first hole transport layer 107. The luminous efficiency of the light-emitting element 101 is reduced. The inventor found through research that a difference between the lowest unoccupied molecular orbital energy level of the first hole transport material and the lowest unoccupied molecular orbital energy level of the first excimer complex is controlled to be greater than 0.2 eV, which is beneficial for reducing the distance from the first luminescent layer 104 to the first hole transport layer 107, thereby ensuring the luminous efficiency of the light-emitting element 101.

Due to the omission of the original first electron barrier layer 106, while the overall thickness of the light-emitting element 101 remains unchanged, the first light-emitting layer 104 can be thickened, and the thickness range of the first light-emitting layer 104 becomes 420 to 636 nanometers.

Please refer to FIGS. 2 to 4. In some embodiments, the first light-emitting unit 101A further comprises a first hole barrier layer 108 located on the side of the first light-emitting layer 104 away from the first electrode 102, and a first electron transfer layer 109 located on the side of the first hole barrier layer 108 away from the first electrode 102. The first hole barrier layer 108 is in direct contact with the first light-emitting layer 104. The first hole barrier layer 108 is in direct contact with the first electron transport layer 109.

The first hole barrier layer 108 comprises a first hole barrier material, wherein a difference between the lowest unoccupied molecular orbital energy level of the first hole barrier material and the lowest unoccupied molecular orbital energy level of the first excimer complex is less than 0.3 eV (such as 0.28 eV, 0.25 eV, 0.22 eV, 0.20 eV, 0.18 eV, 0.15 eV, 0.10 eV, 0.05 eV, etc.), and the first electron transfer layer 109 comprises a first electron transfer material. A difference between the lowest unoccupied molecular orbital energy level of the first electron transfer material and the lowest unoccupied molecular orbital energy level of the first hole barrier material is less than 0.3 eV (such as 0.28 eV, 0.25 eV, 0.22 eV, 0.20 eV, 0.18 eV, 0.15 eV, 0.10 eV, 0.05 eV, etc.), and the first hole barrier layer 108 plays a transitional role between the first electron transfer layer 109 and the first luminescent layer 104, It is beneficial for electrons to be transmitted from the first electron transport layer 109 to the first luminescent layer 104 through the first hole barrier layer 108, thereby reducing the driving voltage of the light-emitting element 101.

A difference between the lowest unoccupied molecular orbital energy level of the second electron barrier material and the lowest unoccupied molecular orbital energy level of the second excimer complex is greater than 0.05 eV (such as 0.06 eV, 0.08 eV, 0.10 eV, 0.12 eV, 0.15 eV, etc.), and a difference between the lowest unoccupied molecular orbital energy level of the second hole transport material and the lowest unoccupied molecular orbital energy level of the second electron barrier material is greater than 0.05 eV, Beneficial to the blocking effect of the second electron barrier layer 110 on electrons from the second luminescent layer 105 to the second electron barrier layer 110, reducing the number of electrons passing from the second luminescent layer 105 to the second hole transport layer 111 through the second electron barrier layer 110, thereby improving the luminous efficiency of the luminescent device.

A difference between the first excited triplet state energy level of the second electron barrier layer 110 and the first excited triplet state energy level of the second excimer complex is greater than 0.15 eV (such as 0.16 eV, 0.18 eV, 0.20 eV, 0.22 eV, 0.25 eV, etc.), which is conducive to energy transfer from the second electron transport layer to the second excimer complex and reduces the driving voltage of the light-emitting element 101.

Please refer to FIG. 4, the second emitting unit 101B further comprises a second hole transport layer 111 located on the side of the second emitting layer 105 near the first electrode 102, which is in direct contact with the second emitting layer 105.

Due to the need for a fine mask plate for the preparation of the second electron barrier layer 110, the cost of the fine mask plate is expensive and the related components of the fine mask plate are frequently replaced, resulting in high preparation costs for the second electron barrier layer 110. By direct contact between the second hole transport layer 111 and the second light-emitting layer 105, the second electron barrier layer 110 is omitted between the second hole transport layer 111 and the second light-emitting layer 105, which saves the fine mask plate required for the preparation of the second electron barrier layer 110 and significantly reduces the manufacturing cost of the light-emitting element 101.

At the same time, omitting the original second electron barrier layer 110 will result in a lack of transition between the second hole transport layer 111 and the second light-emitting layer 105. The difference in the highest occupied molecular orbital energy level between the second hole transport material and the second excimer complex is too large, and the driving voltage increase of the light-emitting element 101 is too large. The power consumption of the light-emitting element 101 increases too much, affecting the product quality of the light-emitting element 101. The inventor found through research that a difference between the highest occupied molecular orbital energy level of the second hole transport material and the highest occupied molecular orbital energy level of the second excimer complex can be controlled to be less than 0.4 eV. The driving voltage increase of the light-emitting element 101 is not significant, and at the same time, the manufacturing cost of the light-emitting element 101 is reduced.

Omitting the original second electron barrier layer 110 will result in a lack of transition between the second hole transport layer 111 and the second luminescent layer 105. The difference in the lowest unoccupied molecular orbital energy levels between the second hole transport material and the second excimer complex is too small, making it easier for electrons to pass from the second luminescent layer 105 to the second hole transport layer 111. The luminous efficiency of the light-emitting element 101 is reduced. The inventor found through research that a difference between the lowest unoccupied molecular orbital energy level of the second hole transport material and the lowest unoccupied molecular orbital energy level of the second excimer complex is controlled to be greater than 0.2 eV, which is beneficial for reducing the distance from the second luminescent layer 105 to the second hole transport layer 111, thereby ensuring the luminous efficiency of the light-emitting element 101.

Meanwhile, due to the omission of the original second electron barrier layer 110, while the overall thickness of the light-emitting element 101 remains unchanged, the second light-emitting layer 105 can be thickened.

Please refer to FIGS. 2 and 4. In some embodiments, the second emitting unit 101B further comprises a second hole barrier layer 112 located on the side of the second emitting layer 105 away from the first electrode 102, and a second electron transfer layer 113 located on the side of the second hole barrier layer 112 away from the first electrode 102. The second hole barrier layer 112 is in direct contact with the second emitting layer 105. The second hole barrier layer 112 is in direct contact with the second electron transport layer 113.

The second hole barrier layer 112 comprises a second hole barrier material, wherein a difference between the lowest unoccupied molecular orbital energy level of the second hole barrier material and the lowest unoccupied molecular orbital energy level of the second excimer complex is less than 0.3 eV (such as 0.28 eV, 0.25 eV, 0.22 eV, 0.20 eV, 0.18 eV, 0.15 eV, 0.10 eV, 0.05 eV, etc.), and the second electron transfer layer 113 comprises a second electron transfer material. A difference between the lowest unoccupied molecular orbital energy level of the second electron transfer material and the lowest unoccupied molecular orbital energy level of the second hole barrier material is less than 0.3 eV (such as 0.28 eV, 0.25 eV, 0.22 eV, 0.20 eV, 0.18 eV, 0.15 eV, 0.10 eV, 0.05 eV, etc.), and the second hole barrier layer 112 plays a transitional role between the second electron transfer layer 113 and the second luminescent layer 105. It is beneficial for electrons to be transmitted from the second electron transport layer 113 to the second luminescent layer 105 through the second hole barrier layer 112, thereby reducing the driving voltage of the light-emitting element 101.

A difference between the highest occupied molecular orbital energy level of the second hole barrier material of the second hole barrier layer 112 and the highest occupied molecular orbital energy level of the second exciton composite is greater than 0.3 eV, preferably, a difference between the highest occupied molecular orbital energy level of the second hole barrier material and the highest occupied molecular orbital energy level of the second exciton composite is greater than 0.4 eV, more preferably. A difference between the highest occupied molecular orbital energy level of the second hole barrier material and the highest occupied molecular orbital energy level of the second excimer complex is greater than 0.5 eV, which is beneficial for blocking holes moving from the second luminescent layer 105 to the second hole barrier layer 112 and improving the luminous efficiency of the light-emitting element 101.

A difference between the first excited triplet state energy level of the second hole barrier material and the first excited triplet state energy level of the second exciton complex is greater than 0.05 eV, which is conducive to energy transfer from the second hole barrier layer 112 to the second exciton complex and reducing the driving voltage of the light-emitting element 101.

Please refer to FIG. 3. In some embodiments, the second emitting unit 101B further comprises a second electron transfer layer 113 located on the side of the second emitting layer 105 away from the first electrode 102, and the second emitting layer 105 is in direct contact with the second electron transfer layer 113.

The second electron transfer layer 113 comprises a second electron transfer material, and a difference between the lowest unoccupied molecular orbital energy level of the second electron transfer material and the lowest unoccupied molecular orbital energy level of the second excimer complex is less than 0.3 eV, which is beneficial for the blocking effect of the second electron transfer layer 113 on holes from the second luminescent layer 105 to the second electron transfer layer 113.

In some embodiments, a difference between the first excited triplet state energy level of the second electron transfer layer 113 and the first excited triplet state energy level of the second excimer complex is greater than 0.05 eV, which facilitates energy transfer from the second electron transfer layer 113 to the second excimer complex and lowers the driving voltage of the light-emitting element 101.

In some embodiments, in the same type of light-emitting element 101, the first electron barrier layer 106 and the second electron barrier layer 110 may exist simultaneously, one of them may exist, or both may not exist. Preferably, the first electron barrier layer 106 and the second electron barrier layer 110 exist simultaneously or both do not exist. When the first electron barrier layer 106 and the second electron barrier layer 110 exist in the same light-emitting element 101, it is beneficial to reduce the driving voltage of the light-emitting element 101 and reduce the power consumption of the light-emitting element 101. When the first electron barrier layer 106 and the second electron barrier layer 110 do not exist in the same light-emitting element 101, it is beneficial to significantly reduce the production cost of the light-emitting element 101 while improving the luminous efficiency of the light-emitting element 101.

In some embodiments, the first hole barrier layer 108 and the second hole barrier layer 112 may exist simultaneously, or one of them in the same light-emitting element 101. Preferably, the first hole barrier layer 108 and the second hole barrier layer 112 coexist in the same light-emitting element 101, which is beneficial for reducing the driving voltage of the light-emitting element 101 and improving the luminous efficiency of the light-emitting element 101.

In some embodiments, the second light-emitting unit 101B is located on the side of the first light-emitting unit 101A near the second electrode 103, or the second light-emitting unit 101B is located on the side of the first light-emitting unit 101A away from the second electrode 103.

When the second emitting unit 101B is located on the side of the first emitting unit 101A near the second electrode 103, the mobility of the second electron transfer layer 113 is smaller than that of the first electron transfer layer 109. The mobility of the first electron transfer layer 109 is the first electron mobility, and the mobility of the second electron transfer layer 113 is the second electron mobility. The second electron mobility is smaller than the first electron mobility, which is more conducive to the separation of holes and electrons within the charge generation layer 119. On the other hand, it is also beneficial for electrons to move faster towards the first luminescent layer 104 through the first electron transfer layer 109, causing electrons to meet holes from the first electrode 102 faster within the first luminescent layer 104, thereby enlarging the area where exciton recombination occurs and moving the exciton recombination area from the side near the first electron transfer layer 109 towards the inside of the first luminescent layer 104, While increasing the region of exciton recombination within the first luminescent layer 104, the triplet exciton annihilation effect is reduced, thereby improving the luminous efficiency of the light-emitting element 101 and extending its lifespan.

When the second emitting unit 101B is located on the side of the first emitting unit 101A near the second electrode 103, the mobility of the second hole transport layer 111 is greater than that of the first hole transport layer 107 of the first emitting unit 101A. The migration rate of the first hole transport layer 107 is the first hole migration rate, and the migration rate of the second hole transport layer 111 is the second hole migration rate. The range of the first hole migration rate is 1.9*10\hat{ }(−4)[m²/(V·s)] to 3.0*10\hat{ }(−4)[m²/(V·s)], such as 2.0*10\hat{ }(−4)[m²/(V·s)], 2.2*10\hat{ }(−4)[m²/(V·s)], 2.5*10\hat{ }(−4)[m²/(V·s)] or 2.8*10\hat{ }(−4)[m²/(V·s)], etc. The range of the second hole mobility is 3.8*10\hat{ }(−4)[m²/(V·s)] to 9.0*10\hat{ }(−4)[m²/(V·s)]. The second hole mobility is greater than the first hole mobility, which is more conducive to the separation of holes and electrons within the charge generation layer 119. On the other hand, it is also beneficial for holes to move faster towards the second luminescent layer 105 through the second hole transport layer 111, causing holes to meet electrons from the second electrode 103 faster within the second luminescent layer 105, thereby enlarging the area where exciton recombination occurs and moving the exciton recombination area from the side near the second hole transport layer 111 towards the inside of the second luminescent layer 105, While increasing the region of exciton recombination within the second luminescent layer 105, the triplet exciton annihilation effect is reduced, thereby improving the luminous efficiency of the light-emitting element 101 and extending its lifespan.

In some embodiments, the charge generation layer 119 comprises a first charge generation sublayer 114 and a second charge generation sublayer 115 located on the side of the first charge generation sublayer 114 away from the first electrode 102.

The first charge generation sublayer 114 comprises a first doped material and a second doped material. The first doped material is different from the second doped material, and the second charge generation sublayer 115 comprises a third doped material and a fourth doped material. The third doped material is different from the fourth doped material.

When the light-emitting element emits light, electrons and holes are generated from the first charge generation sublayer 114, and the second charge generation sublayer 115. The electrons move toward the direction of the first luminescent layer 104, and the holes move toward the direction of the second luminescent layer 105. Preferably, a difference between the lowest unoccupied molecular orbital energy level of the first charge generation sublayer 114 and the highest occupied molecular orbital energy level of the second charge generation sublayer 115 is less than 3 eV, which is conducive to the movement of electrons toward the first charge generation sublayer 114, thereby accelerating the separation of electrons and holes, improving the luminous efficiency of the light-emitting element 101, and extending the service life of the light-emitting element 101.

In the above embodiment, the first electrode 102 is an anode, the second electrode 103 is a cathode, and the first electrode 102 is preferably at least one of metals, alloys, or conductive compounds. Specifically, it can be metal oxides such as indium tin oxide, indium zinc oxide, indium zinc tungsten oxide, indium tin zinc, zinc oxide, or graphene, gold, platinum, nickel, tungsten, chromium, molybdenum, or nitrides of metal materials. The thickness of the first electrode 102 is preferably 960 to 1440 nanometers, more preferably 1100, 1200, or 1300 nanometers.

The second electrode 103 preferably uses a material with a work function lower than that of the first electrode 102. The second electrode 103 is preferably at least one of the metals, alloys, or conductive compounds. Specifically, the material of the second electrode 103 can include alkali metal elements, alkali earth metal elements, rare earth metal elements, such as Ag, Mg, Cu, Al, Pt, Pd, Au, Ni, Nd, Jr, Cr, Li, Ca, LiF/Ca, LiF/Al, Mo, Ti, Yb, W Or magnesium silver alloy, aluminum-lithium alloy, etc. Alternatively, the material of the second electrode 103 can also be selected from indium tin oxide, indium zinc oxide, zinc oxide, indium tin zinc oxide, etc., as well as a combination of optional materials of the second electrode 103 mentioned above. The thickness range of the second electrode 103 is preferably 112 to 168 nanometers, more preferably 130, 140, or 150 nanometers.

In the above embodiments, the first hole transport material and the second hole transport material can be the same or different, and the selection range of the first hole transport material and the second hole transport material can be as follows: phthalocyanine compounds (such as phthalocyanine copper), N1,N1′-([1,1′-biphenyl]-4,4′-diyl) bis (N1-phenyl-N4,N4-di-m-tolylbenzene-1,4-diamine) (DNTPD), 4,4′-[tri (3-methylphenyl) phenylamino] triphenylamine (m-MTDATA) 4,4′-tri (N,N-diphenylamino) triphenylamine (TDATA), 4,4′,4″-tri [N(2-naphthyl)-N-phenylamino]-triphenylamine (2-TNATA), poly (3,4-ethylenedioxythiophene)/poly (4-styrene sulfonate) (PEDOT/PSS), polyaniline/dodecylbenzenesulfonic acid (PANI/DBSA), polyaniline/camphor sulfonate (PANI/CSA), poly aniline/poly (4-styrene sulfonate) (PANI/PSS), N,N-bis (naphthalen-1-yl)-N,N-diphenyl Benzidine (NPB), polyether ketone containing triphenylamine (TPAPEK) 4-isopropyl-4′-methyldiphenyliodonium [tetra (pentafluorophenyl) borate], dipyrazine [2,3-f:2′,3′-h] quinoxaline-2,3,6,7,10,11-hexanitrile (HATCN). Carbazole derivatives such as N-phenylcarbazole and polyethylene-based carbazole, fluorene derivatives. Triphenylamine derivatives such as N,N′-bis (3-methyl phenyl)-N,N′-diphenyl-[1,1 biphenyl]-4,4′-diamine (TPD) and 4,4′,4″-tris (N-carbazolyl) triphenylamine (TCTA), N,N′-bis (naphthalene-1-yl)-N,N′-diphenyl benzidine (NPB), 4,4′-cyclohexylidene bis [N,N-bis (4-methyl phenyl) aniline] (TAPC), 4,4′-bis [N,N′-(3-tolyl) amino]-3,3′-dimethyl biphenyl (HMTPD), 9-(4-tert butyl phenyl)-3,6-bis (triphenyl silyl)-9H carbazole (CzSi), 9-phenyl-9H-3,9′-biphenyl Carbazole (CCP), 1,3-bis (N-carbazolyl) benzene (mCP), 1,3-bis (1,8-dimethyl-9H-carbazole-9-yl) benzene (mDCP) Etc. The combination of compounds with hole transport properties is mentioned above.

In the above embodiment, the first electron barrier material and the second electron barrier material can be the same or different, the selection range of the first electron barrier material can be the same as the selection range of the first hole transmission material, and the selection range of the second electron barrier material can be the same as the selection range of the second hole transmission material. In the same light-emitting element 101. The first electron barrier material and the first hole transport material can be different, and the second electron barrier material and the second hole transport material can be different. Preferably, the first and second electron barrier materials include aromatic amine compounds, such as triarylamine compounds.

In the above embodiments, the first electron transfer material and the second electron transfer material can be the same or different, and the selection range of the first electron transfer material and the second electron transfer material can be: tris (8-hydroxyquinoline) aluminum (Alq3), 1,3,5-tris [(3-pyridinyl)-benz-3-yl] benzene, 2,4,6-tris (3′-(pyridine-3-yl) biphenyl-3-yl)-1,3,5-triazine, 2-(4-(N-phenylbenzimidazol-1-yl) phenyl)-9,10-naphthalene anthracene 1,3,5-tris (1-phenyl-1H-benzo [d] imidazole-2-yl) benzene (TPBi), 2,9-dimethyl-4,7-diphenyl-1,10-phenanthroline (BCP), 4,7 -diphenyl-1,10-phenanthroline (Bphen), 3-(4-biphenyl)-4-phenyl-5-tert-butylphenyl-1,2,4-triazole (TAZ), 4-(naphthalene-1-yl)-3,5-diphenyl-4H-1,2,4 -triazole (NTAZ), 2-(4-biphenyl)-5-(4-tert butyl phenyl)-1,3,4-oxadiazole (tBu-PBD), Liq, BAlq, Bebq2,9,10-di (naphthalene-2-yl) anthracene (ADN) 1,3-bis [3,5-bis (pyridine-3-yl) phenyl] benzene (BmPyPhB). Halogenated metals such as LiF, NaCl, CsF, RbCl, RbI, CuI, KI, lanthanide metals such as Yb, and co-deposited materials of the aforementioned halogenated and lanthanide metals. Metal oxides, such as Li₂O and BaO. A combination of materials with the aforementioned electronic transmission properties. Alternatively, the electron transfer layer can be formed by a mixture of electron transfer materials and insulating organic metal salts, which can include, for example, metal acetate, metal benzoate, metal acetylacetonate, metal acetyl pyruvate, or metal stearate.

In the above embodiment, the first hole barrier material and the second hole barrier material can be the same or different, the selection range of the first hole barrier material can be the same as the selection range of the first electron transfer material, and the selection range of the second hole barrier material can be the same as the selection range of the second electron transfer material. In the same light-emitting element 101. The first hole barrier material can be different from the first electron transfer material, and the second hole barrier material can be different from the second electron transfer material. Preferably, the first hole transport material and the second hole transport material can be heteroaromatic compounds, such as triazine pyrimidine derivatives, etc.

In the above embodiment, when the second light-emitting unit 101B is located on the side of the first light-emitting unit 101A near the second electrode 103, the light-emitting element 101 also comprises a hole injection layer 116 located between the first hole transport layer 107 and the first electrode 102. The hole injection layer 116 comprises a hole injection material, and the selection range of the hole injection material can be: metal oxides such as molybdenum oxide, titanium oxide Tungsten oxide, silver oxide, etc. Phthalocyanine compounds such as copper phthalocyanine. For example, carbazole derivatives such as N-phenyl carbazole and polyethylene carbazole, fluorene derivatives, triphenylamine derivatives such as N,N′-bis (3-methyl phenyl)-N,N′-diphenyl-[1,1 biphenyl]-4,4′-diamine (TPD) and 4,4′,4″-tris (N-carbazolyl) triphenylamine (TCTA),

N,N′-bis (naphthalene-1-yl)-N,N′-diphenyl benzidine (NPB), 4,4′-cyclohexylidene bis [N,N-bis (4-methyl phenyl) aniline] (TAPC), 4,4′-bis [N,N′-(3-tolyl) amino]-3,3′-dimethyl biphenyl (HMTPD), 9-(4-tert butyl phenyl)-3,6-bis (triphenyl silyl)-9H carbazole (CzSi), 9-phenyl-9H-3,9′-biphenyl Carbazole (CCP), 1,3-bis (N-carbazolyl) benzene (mCP), 1,3-bis (1,8-dimethyl-9H-carbazole-9-yl) benzene (mDCP) Wait or a combination of them. The hole injection layer 116 has the hole injection material doped in the hole injection layer 116, with a doping ratio of 1% to 3% (volume fraction). The thickness of the hole injection layer 116 is preferably 80 to 120 nanometers, more preferably 90 nanometers, 100 nanometers, or 110 nanometers.

In the above embodiment, when the second light-emitting unit 101B is located on the side of the first light-emitting unit 101A near the second electrode 103, the light-emitting element 101 also comprises an electron injection layer 117 located between the second electron transfer layer 113 and the second electrode 103. The electron injection layer 117 comprises an electron injection material, which comprises: alkali metal, alkali earth metal, rare earth metal, or alkali metal compounds Alkaline earth metal compounds, rare earth metal compounds, etc., such as lithium, lithium fluoride, lithium oxide, calcium fluoride, ytterbium, Liq, KI, NaCl, CsF, Li₂O, BaO, etc. The work function of the electron injection layer 117 is lower than that of the second electrode 103, which is beneficial for injecting electrons into the electron transport layer. The thickness of the electron injection layer 117 is preferably 8 to 12 nanometers, more preferably 9, 10, or 11 nanometers.

In the above embodiment, the selection range of the first doped material is the same as the selection range of the “first electron transfer material” or “second electron transfer material” in the light-emitting element 101, and the selection range of the second doped material is the same as the selection range of the “charge injection material” in the light-emitting element 101. In the first charge generation sublayer 114, the doping ratio of the first doped material to the second doped material is 88:12 to 99:1, such as 88:12, 90:10, 92:8, 93:7, 95:5, 96:4, 98:2, etc., preferably 93:7 to 95:5, such as 94:6, 95:5, 96:4, etc. Among them, the doping ratio refers to the ratio of the volume occupied by the first doped material in the first charge generation sublayer 114 to the volume occupied by the second doped material. The thickness of the first charge generation sublayer 114 can be from 80 to 120 nanometers, preferably from 90 to 110 nanometers, and more preferably from 100 nanometers.

In the above embodiment, the selection range of the third doped material is the same as the selection range of the “first hole transmission material” or “second hole transmission material” in the light-emitting element 101, and the selection range of the fourth doped material is the same as the selection range of the “hole injection material” in the light-emitting element 101. In the second charge generation sublayer 115, the doping ratio of the third doped material to the fourth doped material is 88:12 to 99:1, such as 88:12, 90:10, 92:8, 93:7, 95:5, 96:4, 98:2, etc., preferably 93:7 to 95:5, such as 94:6, 95:5, 96:4, etc. Among them, the doping ratio refers to the ratio of the volume occupied by the third doped material in the second charge generation sublayer 115 to the volume occupied by the fourth doped material. The thickness of the second charge generation sublayer 115 can be from 80 to 120 nanometers, preferably from 90 to 110 nanometers, and more preferably from 100 nanometers.

In the above embodiment, the light-emitting element 101 can also include a cover layer 118 located on the second electrode 103, and the material of the cover layer 118 can be organic or inorganic material. When the material of the covering layer 118 is an inorganic material, the inorganic material can include alkali metal compounds, such as LiF, or alkali earth metal compounds, such as MgF₂, SiON, SiNₓ, SiO_{y}, or a combination of them. When the material of the covering layer 118 is an organic material, the organic material can include α-NPD, NPB, TPD, m-MTDATA, Alq3, CuPc, N4,N4,N4′,N4′-tetra (biphenyl-4 yl) biphenyl-4,4′-diamine (TPD15), 4,4′,4″-tri (carbazol-9 yl) triphenylamine (TCTA), epoxy resin, or acrylic ester (such as methacrylate), or a combination of them. The thickness of the covering layer 118 is preferably 520 to 960 nanometers, more preferably 650 to 800 nanometers, such as 680 nanometers, 700 nanometers, 750 nanometers, 780 nanometers, etc.

In the above embodiment, the first luminescent layer 104 and the second luminescent layer 105 are preferably ¼ of the microcavity formed between the first electrode and the second electrode of the light-emitting element 101λ And ¾λ Of which, λ The peak wavelength of the emission peak formed by the light emitted by the first light-emitting element 101 is used to enhance the light output efficiency of the light-emitting element 101 through interference enhancement.

Below is a specific comparative case study of a set of light-emitting elements for illustration.

### Example 1

The anode in light-emitting element 1 is an indium tin oxide electrode with a thickness of 1100 nanometers; and the thickness of the first luminescent layer in the light-emitting element 1 is 390 nanometers. The structural formulas of the first main body material, second main body material, first auxiliary material, and first guest material in the first luminescent layer of the light-emitting element 1 are as follows:

The first main body material and the second main body material:

the first main body material:

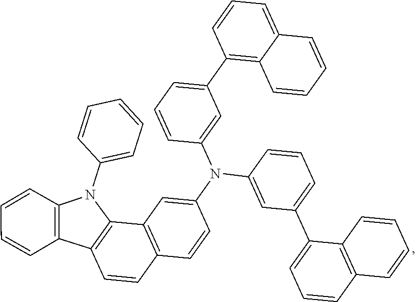 [SMILES: c1ccc(-n2c3ccccc3c3ccc4ccc(N(c5cccc(-c6cccc7ccccc67)c5)c5cccc(-c6cccc7ccccc67)c5)cc4c32)cc1]

the second main body material:

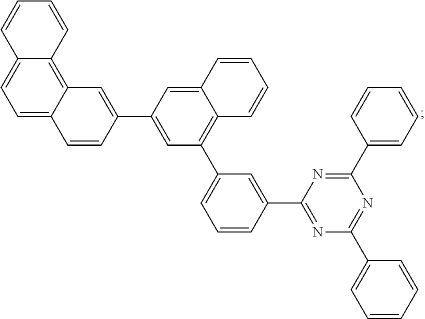 [SMILES: c1ccc(-c2nc(-c3ccccc3)nc(-c3cccc(-c4cc(-c5ccc6ccc7ccccc7c6c5)cc5ccccc45)c3)n2)cc1]

the first auxiliary material:

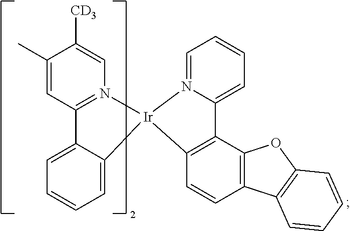

first guest material:

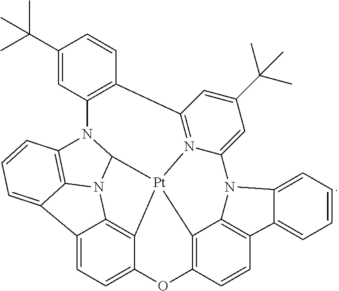

Within the first luminescent layer, the volume ratio of the first main body material to the second main body material to the first auxiliary material to the first guest material is 44:44:6:6, and the thickness of the first luminescent layer is 390 nanometers.

The material composition and structural formula of the other film layers in the first emitting unit of the light-emitting element 1 are as follows:

the first hole transport layer:

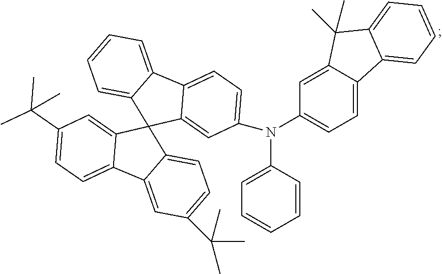 [SMILES: CC(C)(C)c1ccc2c(c1)-c1ccc(C(C)(C)C)cc1C21c2ccccc2-c2ccc(N(c3ccccc3)c3ccc4c(c3)C(C)(C)c3ccccc3-4)cc21]

the first electron barrier layer:

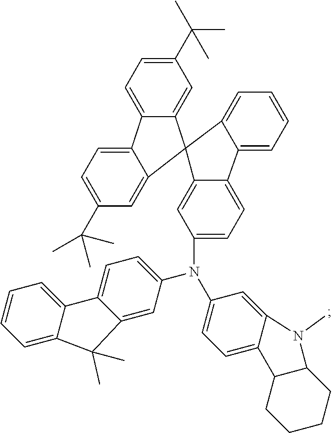 [SMILES: CN1c2cc(N(c3ccc4c(c3)C(C)(C)c3ccccc3-4)c3ccc4c(c3)C3(c5ccccc5-4)c4cc(C(C)(C)C)ccc4-c4ccc(C(C)(C)C)cc43)ccc2C2CCCCC21]

the first hole barrier layer:

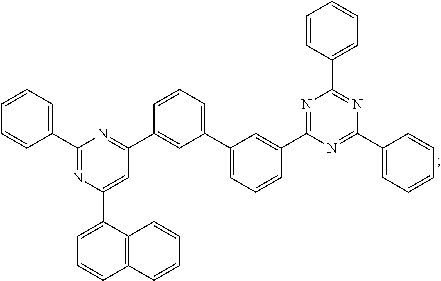 [SMILES: c1ccc(-c2nc(-c3cccc(-c4cccc(-c5nc(-c6ccccc6)nc(-c6ccccc6)n5)c4)c3)cc(-c3cccc4ccccc34)n2)cc1]

the first electronic transport layer:

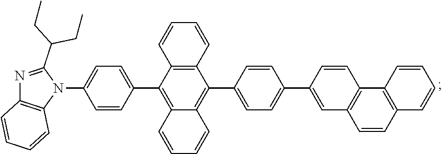 [SMILES: CCC(CC)c1nc2ccccc2n1-c1ccc(-c2c3ccccc3c(-c3ccc(-c4ccc5c(ccc6ccccc65)c4)cc3)c3ccccc23)cc1]

the thickness of the first hole transport layer is 250 nanometers, the thickness of the first electron barrier layer is 120 nanometers, the thickness of the first hole barrier layer is 40 nanometers, and the thickness of the first electron transport layer is 150 nanometers.

The thickness and material composition of the second light-emitting layer in the light-emitting element 1 are the same as those of the first light-emitting layer in the light-emitting element 1, and will not be repeated here.

The material composition and structural formula of other film layers in the second emitting unit of light-emitting element 1 are as follows:
the second hole transport layer: N,N-bis (naphthalen-1-yl)-N,N-diphenylbenzidine;
the second electron barrier layer: 4,4′,4″-tri (N-carbazolyl) triphenylamine;
   the second hole barrier layer:

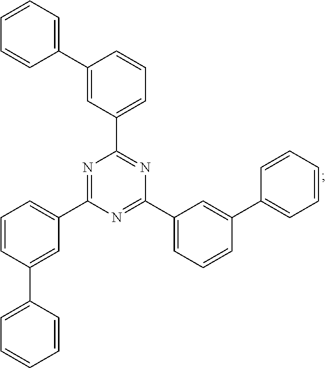 [SMILES: c1ccc(-c2cccc(-c3nc(-c4cccc(-c5ccccc5)c4)nc(-c4cccc(-c5ccccc5)c4)n3)c2)cc1]

the second electron transport layer:

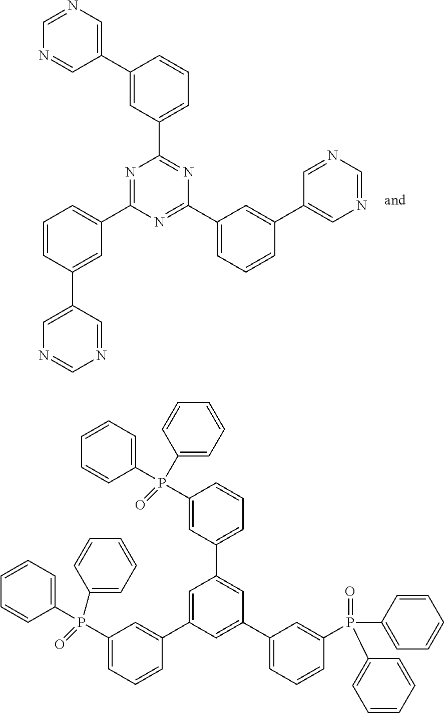 [SMILES: c1cc(-c2cncnc2)cc(-c2nc(-c3cccc(-c4cncnc4)c3)nc(-c3cccc(-c4cncnc4)c3)n2)c1 ; O=P(c1ccccc1)(c1ccccc1)c1cccc(-c2cc(-c3cccc(P(=O)(c4ccccc4)c4ccccc4)c3)cc(-c3cccc(P(=O)(c4ccccc4)c4ccccc4)c3)c2)c1]

deposited at a volume ratio of 5:5;
in the light-emitting element 1, the thickness of the second hole transport layer is 420 nanometers, the thickness of the second electron barrier layer is 120 nanometers, the thickness of the second hole barrier layer is 50 nanometers, and the thickness of the second electron transport layer is 310 nanometers.

In the light-emitting element 1, the hole injection layer is composed of

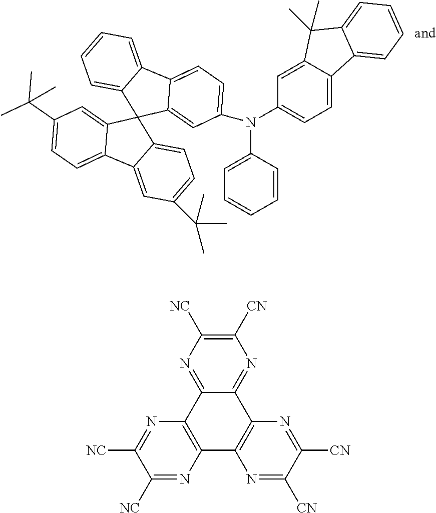 [SMILES: CC(C)(C)c1ccc2c(c1)-c1ccc(C(C)(C)C)cc1C21c2ccccc2-c2ccc(N(c3ccccc3)c3ccc4c(c3)C(C)(C)c3ccccc3-4)cc21 ; N#Cc1nc2c3nc(C#N)c(C#N)nc3c3nc(C#N)c(C#N)nc3c2nc1C#N]

deposited at a volume ratio of 97:3, with a thickness of 110 micrometers.

In the light-emitting element 1, the first charge generation sublayer is composed of

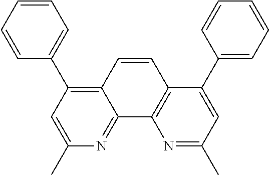 [SMILES: Cc1cc(-c2ccccc2)c2ccc3c(-c4ccccc4)cc(C)nc3c2n1]

deposited with Li in a volume ratio of 95:5, with a thickness of 100 micrometers.

In the light-emitting element 1, the second charge generation sublayer is composed of N,N′-bis (3-methyl phenyl)-N,N′-diphenyl-[1,1 biphenyl]-4,4′-diamine and

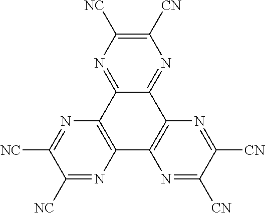 [SMILES: N#Cc1nc2c3nc(C#N)c(C#N)nc3c3nc(C#N)c(C#N)nc3c2nc1C#N]

deposited at a volume ratio of 95:5, with a thickness of 100 micrometers.

In light-emitting element 1, the electron injection layer is formed by Yb deposition, with a thickness of 10 nanometers.

In the light-emitting element 1, the second electrode is formed by depositing Ag and Mg in a volume ratio of 90:10, with a thickness of 130 nanometers.

In the light-emitting element 1, the covering layer is composed of

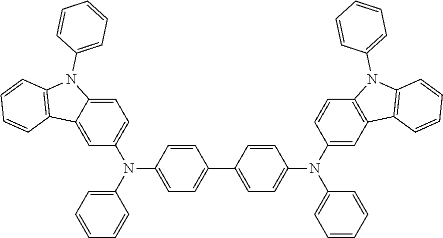 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

formed by sedimentation, with a thickness of 700 micrometers.

### Example 2

The manufacturing method of light-emitting element 2 is the same as that of light-emitting element 1, and the composition of each film layer is the same. The difference is that:

The material composition of the first light-emitting layer of light-emitting element 2 is the same as that of light-emitting element 1, with a thickness of 510 nanometers.

The material composition and thickness of the second light-emitting layer of the light-emitting element 2 are the same as those of the first light-emitting layer of the light-emitting element 2.

The light-emitting element 2 does not have a first electron barrier layer and a second electron barrier layer.

The material composition and thickness of the first electrode, hole injection layer, first hole transport layer, first hole barrier layer, first electron transport layer, first charge generation sublayer, second charge generation sublayer, second hole transport layer, second hole barrier layer, second electron transport layer, electron injection layer, second electrode, and cover layer in the light-emitting element 2 are the same as those of the corresponding film layer in the light-emitting element 1.

### Proportion 1

The manufacturing method of Comparison element 1 is the same or similar to that of light-emitting element 1 and light-emitting element 2, with the difference being:
Comparison element 1 only comprises one luminescent unit, that is, the composition and thickness of the film layer of comparison element 1 are:
The composition and thickness of the first electrode are the same as those of the first electrode of the light-emitting element 1.
The hole injection layer has the same composition and thickness as the first hole injection layer of the light-emitting element 1.
The composition and thickness of the hole transport layer are the same as those of the first hole transport layer of the light-emitting element 1.
The composition and thickness of the electron barrier layer are the same as those of the first electron barrier layer of the light-emitting element 1.
The composition and thickness of the luminescent layer are the same as those of the first luminescent layer of the light-emitting element 1.
The hole barrier layer has the same composition and thickness as the first hole barrier layer of the light-emitting element 1.
The composition and thickness of the electron transport layer are the same as those of the first electron transport layer of the light-emitting element 1.
The composition and thickness of the electron injection layer are the same as those of the electron injection layer of the light-emitting element 1.

### Proportion 2

The light-emitting elements 1 and 2 of comparison element 2 are the same or similar, except that the first light-emitting layer in comparison element 2 does not contain the first auxiliary material, and the second light-emitting layer in comparison element 2 does not contain the second auxiliary material.

In the first luminescent layer of Comparison element 2, the volume ratio of the first main body material to the second main body material to the first guest material is 44:44:6:6, while in the second luminescent layer, the volume ratio of the third main body material to the fourth main body material to the second guest material is 44:44:6:6

For light-emitting elements 1-2 and comparison element 1, measure and display in Table 1 the current efficiency obtained by dividing the initial brightness by the current density based on the percentage value of comparison element 1, the driving voltage at the initial brightness, and the time it takes for the luminous brightness to decrease to 95% of the initial brightness under the same initial brightness conditions (T95 service life at the same brightness) The time when the luminous brightness decreases to 95% of the initial brightness under the same current density conditions (T95 service life under the same current density).

TABLE 1
Performance Test Results of Light-emitting Element 1,
Light-emitting Element 2, and Comparison element 1

| | | | | T95 service life |
|---|---|---|---|---|
| | Current | Drive | T95 service life | at the same |
| | efficiency | voltage | at the same | current density |
| | (%) | (%) | brightness (%) | (%) |
| Comparison | 100 | 100 | 100 | 100 |
| element 1 | | | | |
| Light-emitting | 183 | 192 | 290 | 113 |
| element 1 | | | | |
| Light-emitting | 179 | 204 | 310 | 150 |
| element 2 | | | | |

Please refer to Table 1, which indicates that light-emitting element 1 and light-emitting element 2 have higher current efficiency and longer service life compared to Comparison element 1, that is, light-emitting element 1 and light-emitting element 2 have higher luminous efficiency and longer service life. In addition, compared to light-emitting element 1, light-emitting element 2 has higher current efficiency and service life, and the increase in driving voltage and decrease in current efficiency are not significant. This indicates that the removal of the first and second electron barrier layers has led to a limited increase in driving voltage, and the impact on luminous efficiency is not significant, significantly extending the service life of the light-emitting element. At the same time, the initial brightness of light-emitting element 1 and light-emitting element 2 has significantly improved compared to comparison element 1, indicating a significant improvement in luminous efficiency with the introduction of the first and second light-emitting layers.

For light-emitting elements 1-2 and comparison element 2, measure and display the current efficiency obtained by dividing the initial brightness by the current density based on the percentage value of comparison element 2 in Table 1, the driving voltage at the initial brightness, and the time when the luminous brightness decreases to 95% of the initial brightness under the same current density conditions (T95 service life at the same brightness).

TABLE 2
Performance Test Results of Light-emitting Element 1,
Light-emitting Element 2, and Comparison element 2

| | | | T95 service life |
|---|---|---|---|
| | Current | Drive | under the same |
| | efficiency | voltage | current density |
| | (%) | (%) | (%) |
| Comparison element 2 | 100 | 100 | 100 |
| Light-emitting element 1 | 102 | 97 | 170 |
| Light-emitting element 2 | 98 | 104 | 227 |

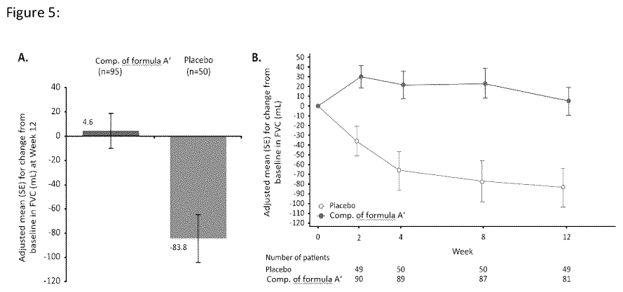

Please refer to Table 2 and FIG. 5. Similar to the results in Table 1, light-emitting element 1 and light-emitting element 2 have higher current efficiency and longer service life compared to Comparison element 2, that is, light-emitting element 1 and light-emitting element 2 have higher luminous efficiency and longer service life. In addition, compared to light-emitting element 1, light-emitting element 2 has higher current efficiency and service life, and the increase in driving voltage and decrease in current efficiency are not significant. This indicates that the removal of the first and second electron barrier layers has led to a limited increase in driving voltage, and the impact on luminous efficiency is not significant, significantly extending the service life of the light-emitting element.

The embodiment of the present disclosure increases the path for energy transfer from the first excimer complex to the first guest material by setting the first luminescent unit 101A and the second luminescent unit 101B in the light-emitting element 101, and adding the first luminescent layer 104 in the first luminescent unit 101A to the first auxiliary material, and the first excited triplet state energy level of the first auxiliary material is between the first excimer complex and the first excited triplet state energy level of the first guest material, This reduces the energy loss during the energy transfer process, ensures the luminous efficiency of the light-emitting element 101, and extends the service life of the light-emitting element 101.

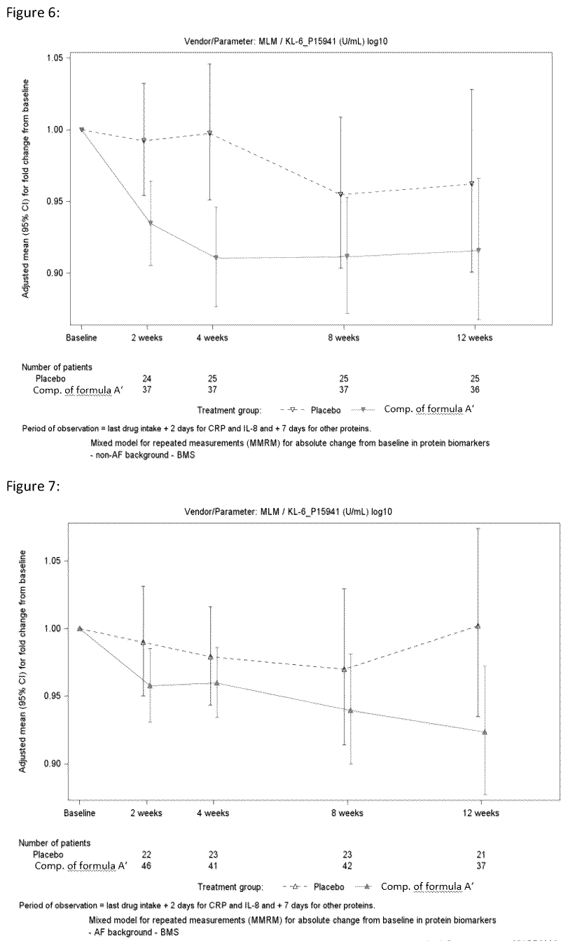

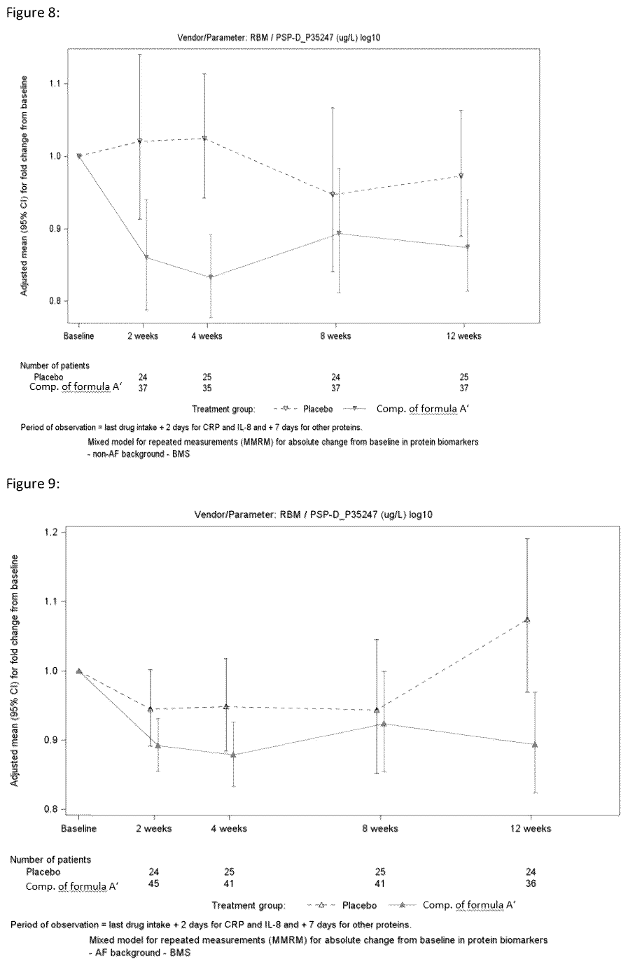

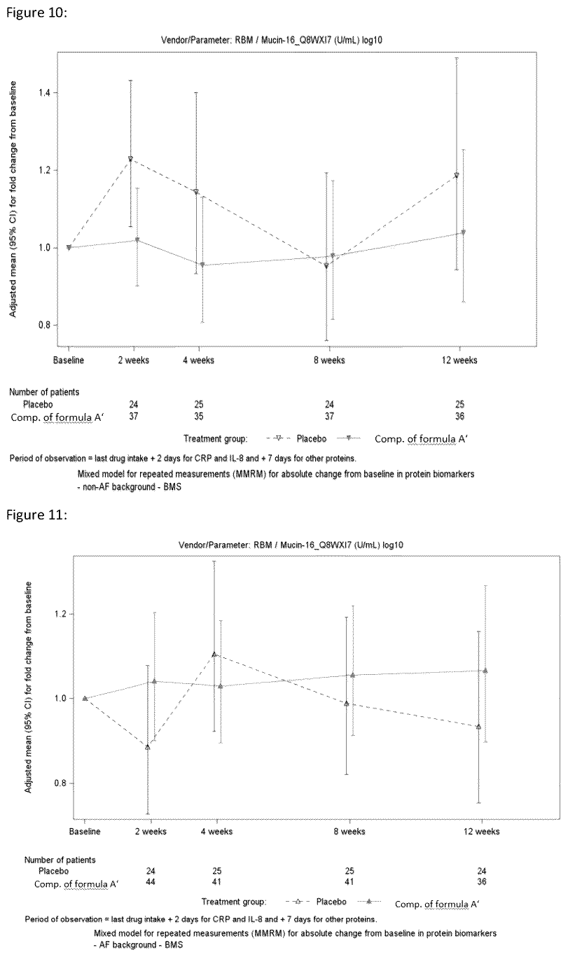

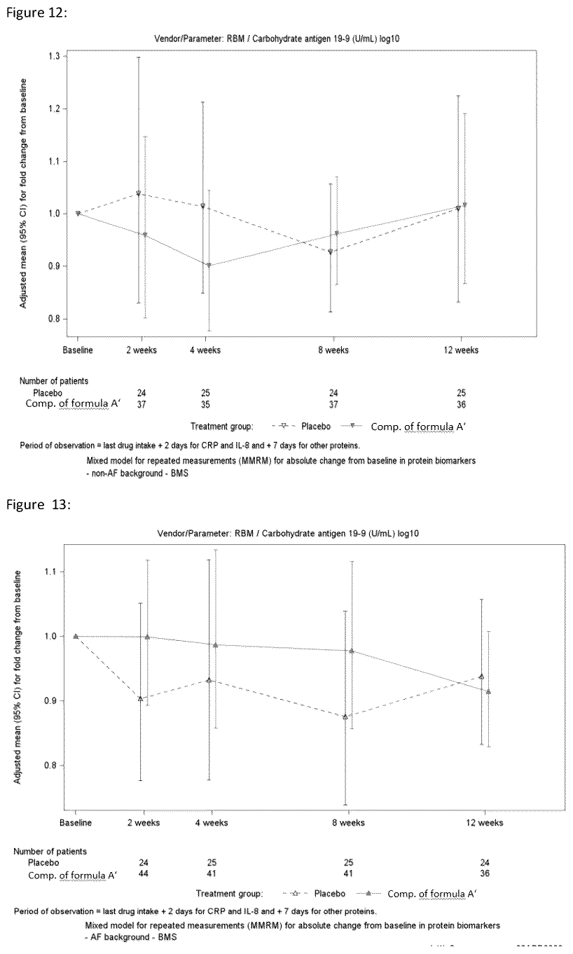

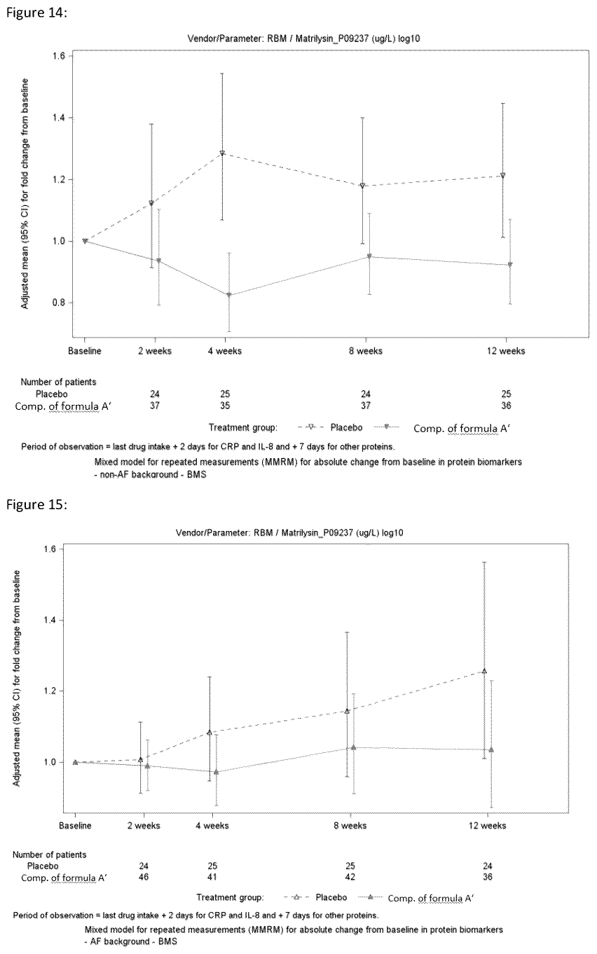

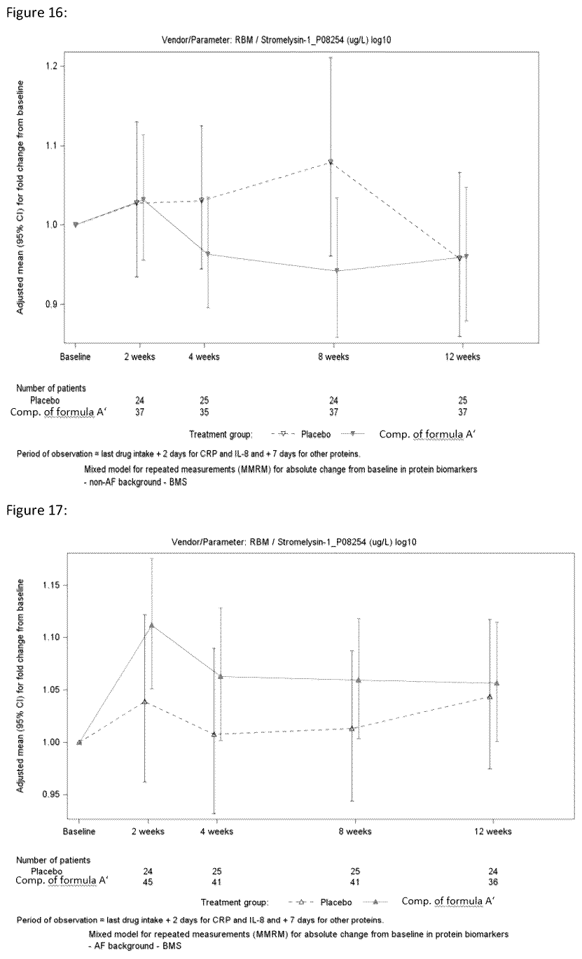

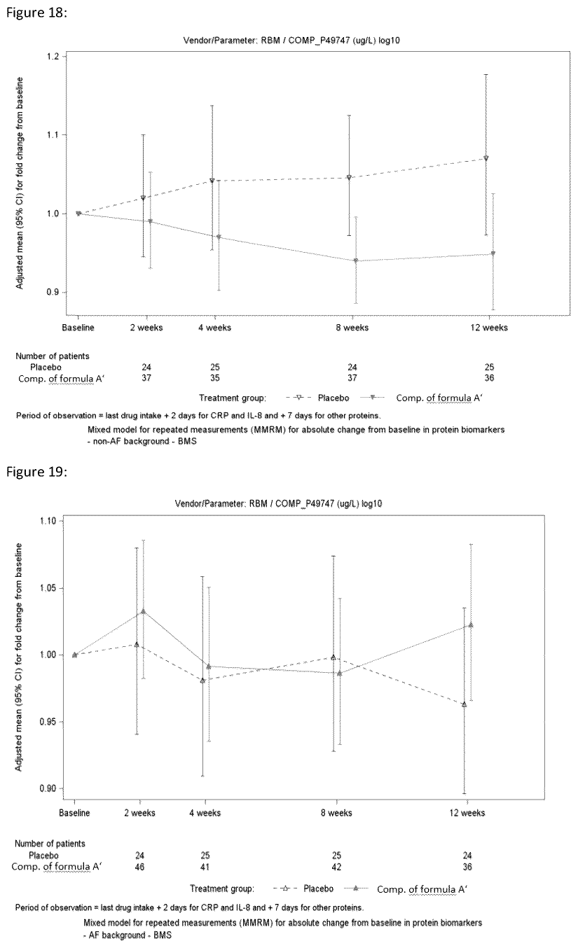

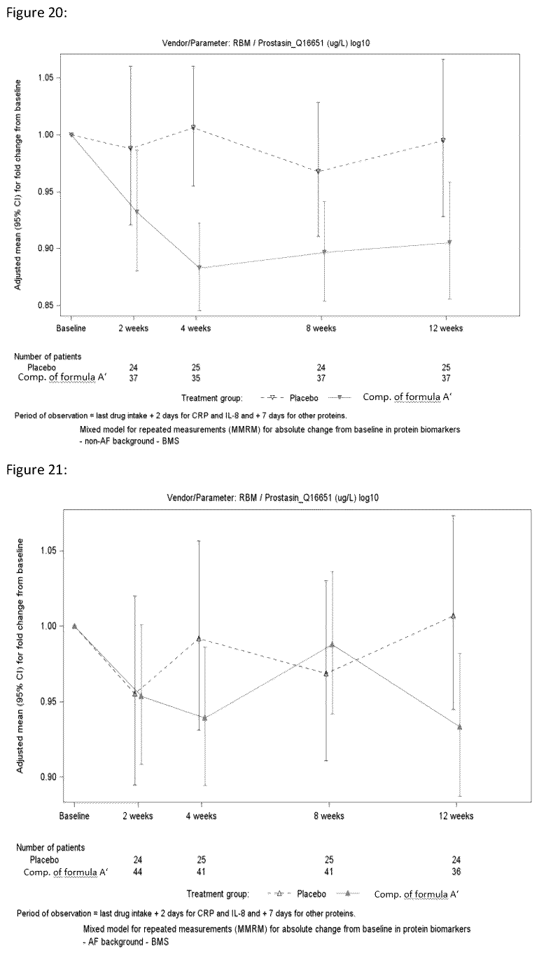

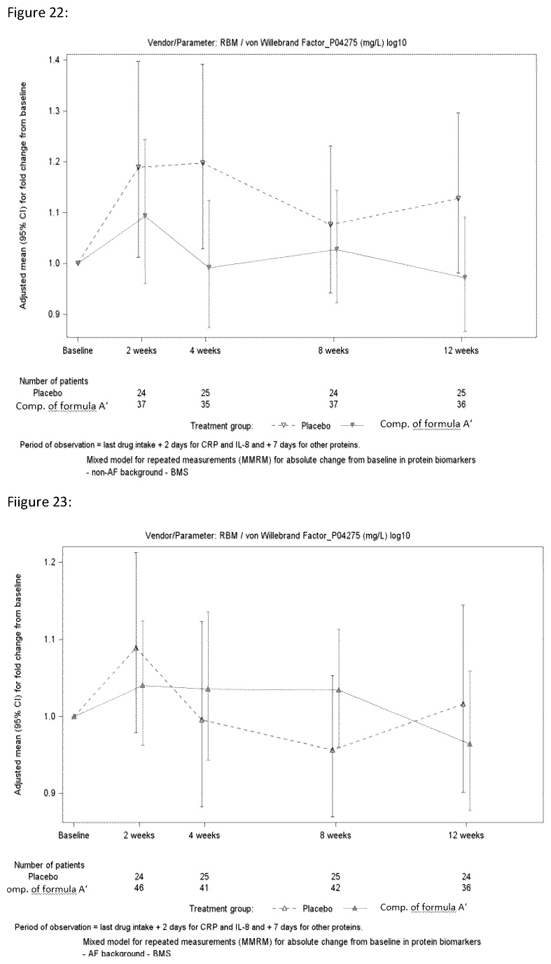

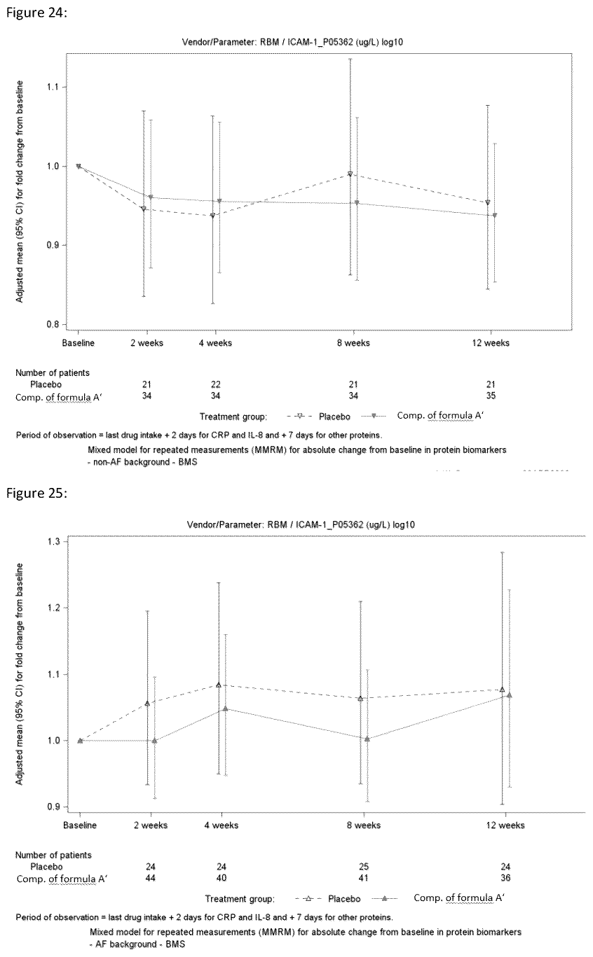

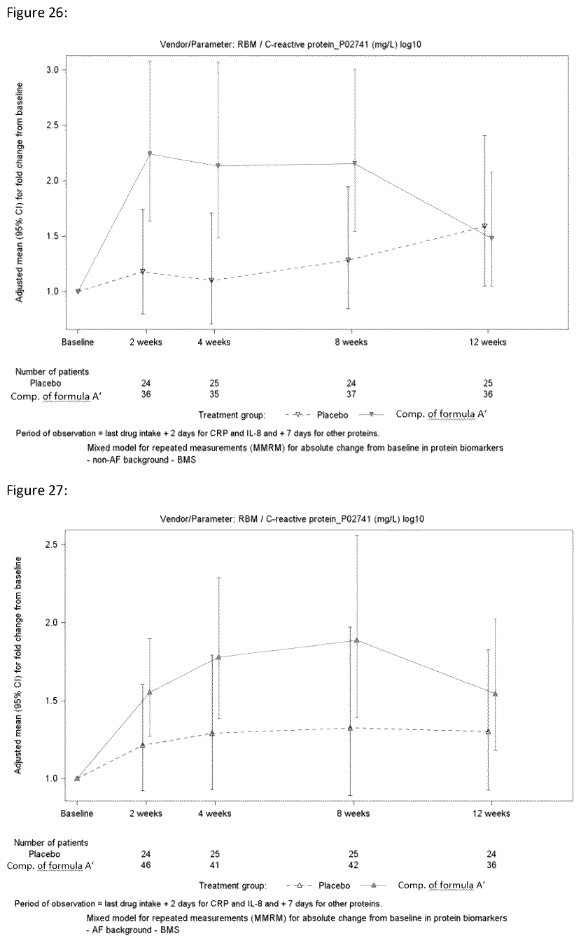

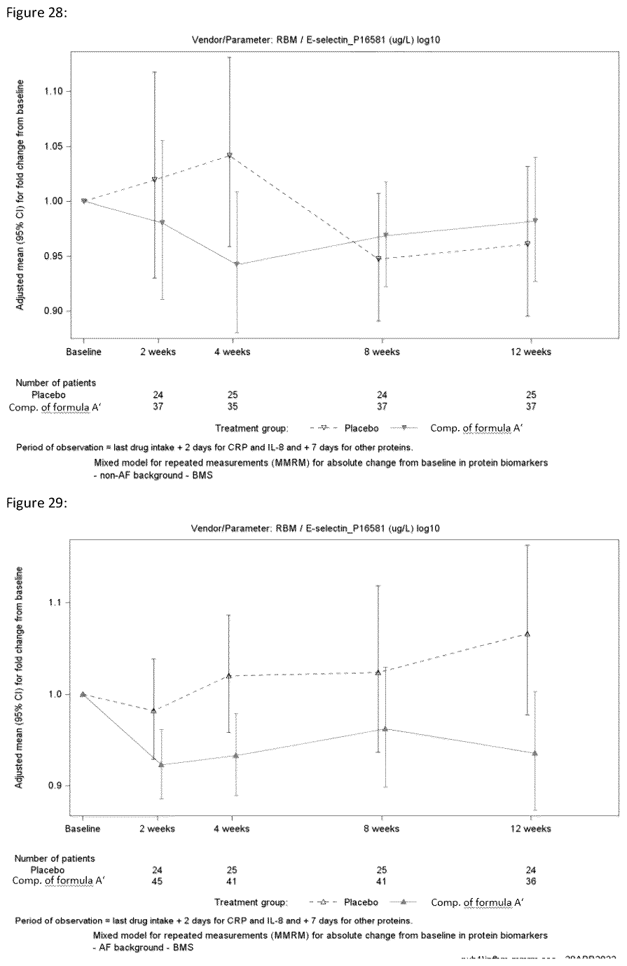

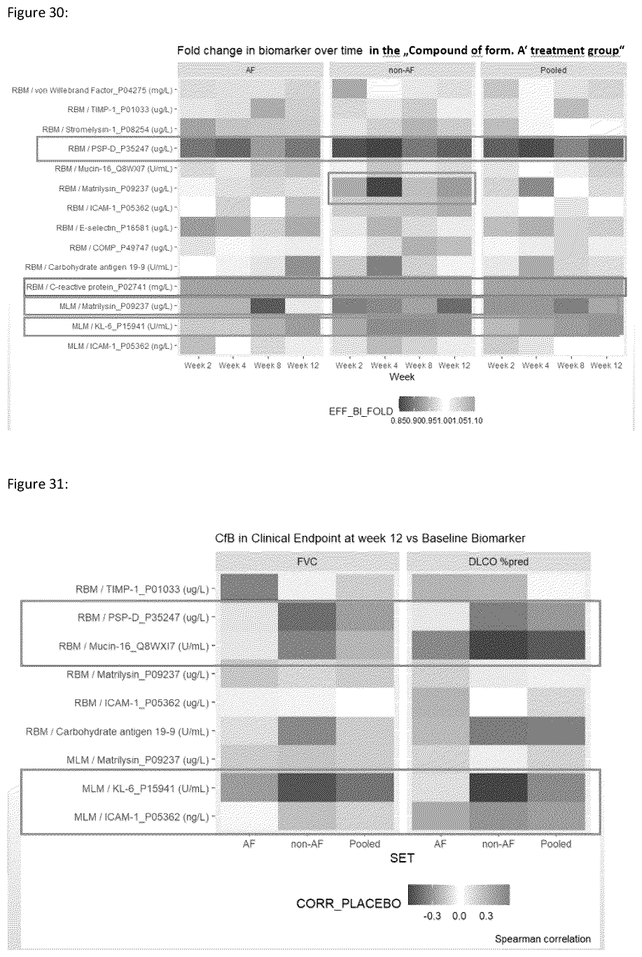

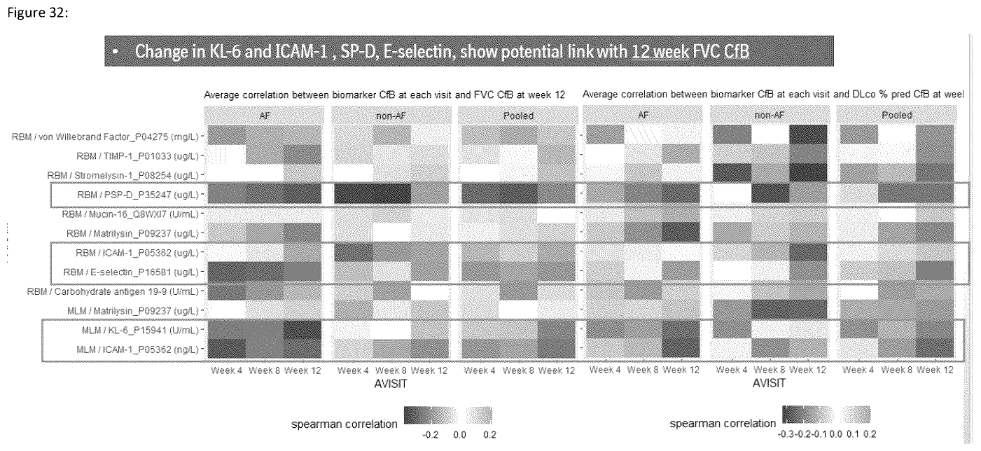

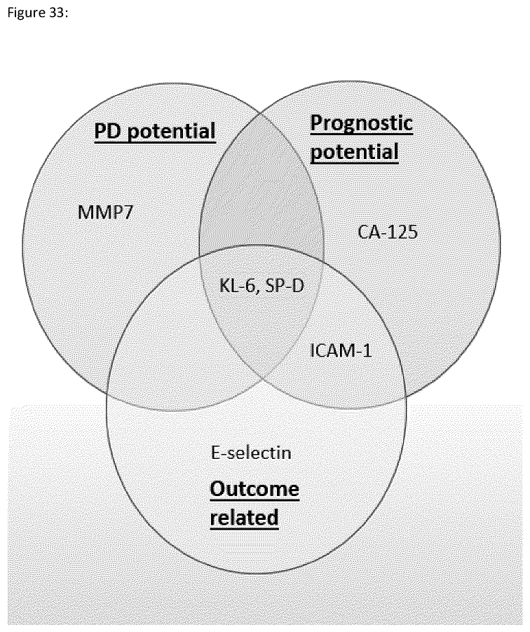

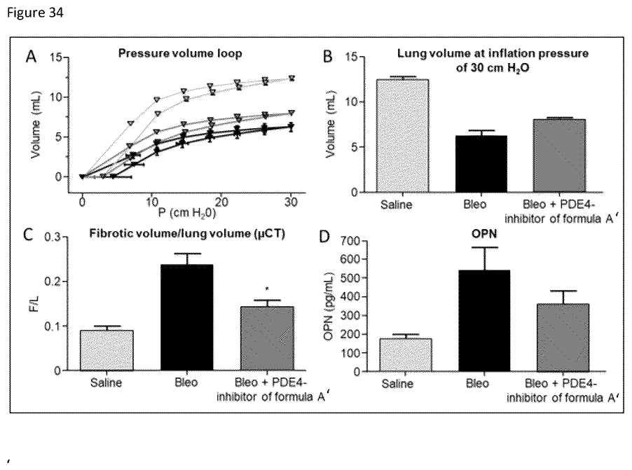

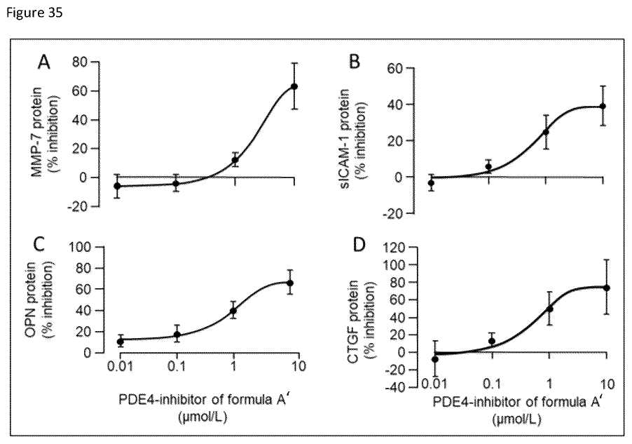

Please refer to FIG. 6. The embodiment of the present disclosure also provides a display panel 10, including a light-emitting element 101 as previously described.

In some embodiments, the display panel 10 comprises a red light-emitting element, a green light-emitting element, and a blue light-emitting element. At least one of the red light-emitting element, green light-emitting element, and blue light-emitting element adopts a light-emitting element 101 as described above. Preferably, the red light-emitting element, green light-emitting element, and blue light-emitting element all adopt any of the aforementioned light-emitting elements 101, which is beneficial for improving the overall luminous efficiency of the display panel 10 while extending its service life.

When the green light-emitting element is any of the aforementioned light-emitting elements, the green light-emitting element comprises a first green light-emitting unit electrode and a second green light-emitting unit electrode.

The green light-emitting element further comprises a first green light-emitting unit and a second green light-emitting unit. The first green light-emitting unit comprises a first green light-emitting layer and a first green light-emitting unit hole transport layer located on the side near the electrode of the first green light-emitting unit. The first green light-emitting layer is in direct contact with the first green light-emitting unit hole transport layer.

The second green light-emitting unit comprises a second green light-emitting layer and a second green light-emitting unit hole transport layer located on the side of the second green light-emitting layer near the electrode of the first green light-emitting unit. The second green light-emitting layer is in direct contact with the second green light-emitting unit hole transport layer.

By direct contact between the first green light-emitting layer and the first green light-emitting unit hole transport layer, and direct contact between the second green light-emitting layer and the second green light-emitting unit hole transport layer, the manufacturing cost of the green light-emitting element is significantly reduced, and the luminous efficiency of the green light-emitting element is improved, thereby reducing the manufacturing cost of the display panel and improving the luminous efficiency of the display panel.

In some embodiments, when the red light-emitting element is any of the aforementioned light-emitting elements 101, the red light-emitting element comprises a first red light-emitting unit electrode and a second red light-emitting unit electrode.

The red light-emitting element further comprises a first red light-emitting unit and a second red light-emitting unit. The first red light-emitting unit comprises a first red light-emitting layer and a first red light-emitting unit hole transport layer located on the side near the electrode of the first red light-emitting unit. The first red light-emitting layer is in direct contact with the first red light-emitting unit hole transport layer. Alternatively, the second red light-emitting unit comprises a second red light-emitting layer and a second red light-emitting unit hole transport layer located on the side of the second red light-emitting layer near the electrode of the first red light-emitting unit, wherein the second red light-emitting layer is in direct contact with the second red light-emitting unit hole transport layer.

Alternatively, the second red light-emitting unit further comprises a second red light-emitting unit electron barrier layer located between the second red light-emitting layer and the second red light-emitting unit hole transport layer, wherein the second red light-emitting unit electron barrier layer is in direct contact with the second red light-emitting layer, and the second red light-emitting unit electron barrier layer is in direct contact with the second red light-emitting unit hole transport layer. Alternatively, the second red light-emitting unit further comprises a second red light-emitting unit electron barrier layer located between the second red light-emitting layer and the second red light-emitting unit hole transport layer, wherein the second red light-emitting unit electron barrier layer is in direct contact with the second red light-emitting layer, and the second red light-emitting unit electron barrier layer is in direct contact with the second red light-emitting unit hole transport layer.

In some embodiments, when the blue light-emitting element is any of the aforementioned light-emitting elements 101, the blue light-emitting element comprises a first blue light-emitting unit electrode and a second blue light-emitting unit electrode.

The blue light-emitting element further comprises a first blue light-emitting unit and a second blue light-emitting unit. The first blue light-emitting unit comprises a first blue light-emitting layer and a first blue light-emitting unit hole transport layer located on the side near the electrode of the first blue light-emitting unit. The first blue light-emitting layer is in direct contact with the first blue light-emitting unit hole transport layer. Alternatively, the second blue light-emitting unit comprises a second blue light-emitting layer and a second blue light-emitting unit hole transport layer located on the side of the second blue light-emitting layer near the electrode of the first blue light-emitting unit, wherein the second blue light-emitting layer is in direct contact with the second blue light-emitting unit hole transport layer.

Alternatively, the second blue light-emitting unit further comprises a second blue light-emitting unit electron barrier layer located between the second blue light-emitting layer and the second blue light-emitting unit hole transport layer, wherein the second blue light-emitting unit electron barrier layer is in direct contact with the second blue light-emitting layer, and the second blue light-emitting unit electron barrier layer is in direct contact with the second blue light-emitting unit hole transport layer. Alternatively, the second blue light-emitting unit further comprises a second blue light-emitting unit electron barrier layer located between the second blue light-emitting layer and the second blue light-emitting unit hole transport layer, wherein the second blue light-emitting unit electron barrier layer is in direct contact with the second blue light-emitting layer, and the second blue light-emitting unit electron barrier layer is in direct contact with the second blue light-emitting unit hole transport layer.

The display panel 10 also comprises an array substrate 201 located on one side of the light-emitting element 101, and a packaging layer located on the side of the light-emitting element 101 away from the array substrate 201 and covering the light-emitting element 101.

The display panel 10 also comprises a polarizer layer located on the side of the packaging layer away from the light-emitting element 101 and a cover layer located on the side of the polarizer layer away from the light-emitting element 101. Among them, the polarizing film layer can be replaced by a color film layer, which can include multiple color resistances and a black matrix located on both sides of the color resistance.

The display panel 10 provided by the embodiment of the present disclosure comprises a first emitting unit 101A and a second emitting unit 101B in the emitting element 101, and a first emitting layer 104 in the first emitting unit 101A is added to the first auxiliary material, and the first excited triplet state energy level of the first auxiliary material is between the first excited triplet state energy level of the first excimer complex and the first excited triplet state energy level of the first guest material. The path for energy transfer from the first excimer complex to the first guest material has been increased, reducing energy loss during the energy transfer process, ensuring the luminous efficiency of the light-emitting element 101 while extending its service life.

The embodiment of the present disclosure discloses a light-emitting element and a display panel, which comprises a pair of electrodes, a first light-emitting unit located between the pair of electrodes, a second light-emitting unit, a first light-emitting unit comprising a first light-emitting layer, a second light-emitting unit comprising a second light-emitting layer, a charge generation layer located between the first light-emitting unit and the second light-emitting unit, a first light-emitting layer comprising a first main body material, a second main body material The first object material and the first auxiliary material form a first excimer complex with the second object material. The first excited triplet energy level of the first auxiliary material is between the first excimer complex and the first excited triplet energy level of the first object material. The present disclosure increases the path of energy transfer from the first excimer complex to the first object material by adding the first auxiliary material, This reduces energy loss during the energy transfer process, ensures the luminous efficiency of the light-emitting element, and extends the service life of the light-emitting element.

The above provides a detailed introduction to a light-emitting element and a display panel provided by the embodiments of the present disclosure. This article applies specific examples to explain the principles and implementation methods of the present disclosure. The explanations of the above embodiments are only used to help understand the methods and core ideas of the present disclosure. Meanwhile, for technical personnel in this field, there may be changes in the specific implementation methods and application scope based on the ideas of the present disclosure. In summary, the content of this specification should not be understood as a limitation of the present disclosure.

What is claimed is:

1. A light-emitting element, comprising:
a pair of electrodes, comprising a first electrode and a second electrode;
a first light-emitting unit, located between the pair of electrodes, wherein the first light-emitting unit comprises a first light-emitting layer;
a second light-emitting unit, located between the pair of electrodes, wherein the second light-emitting unit comprises a second light-emitting layer;
a charge generation layer, located between the first light-emitting unit and the second light-emitting unit; and
a first luminescent layer, comprising a first main body material, a second main body material, a first guest material, and a first auxiliary material, wherein the first main body material forms a first excimer complex with the second main body material;
wherein a first excited triplet state energy level of the first auxiliary material is lower than a first excited triplet state energy level of the first excimer complex, and the first excited triplet state energy level of the first auxiliary material is higher than a first excited triplet state energy level of the first guest material.

2. The light-emitting element as claimed in claim 1, wherein the first light-emitting unit further comprises a first hole transport layer located on the side near the first electrode of the first light-emitting layer, and the first hole transport layer is in direct contact with the first light-emitting layer;
the first hole transport layer comprises a first hole transport material, and a difference between a highest occupied molecular orbital energy level of the first hole transport material and a highest occupied molecular orbital energy level of the first excimer complex is less than 0.4 eV.

3. The light-emitting element as claimed in claim 2, wherein a difference between a lowest unoccupied molecular orbital energy level of the first hole transport material and a lowest unoccupied molecular orbital energy level of the first excimer complex is greater than 0.2 eV.

4. The light-emitting element as claimed in claim 1, wherein the first light-emitting unit comprises a first electron barrier layer and a first hole transport layer located on the side near the first electrode of the first electron barrier layer, the first electron barrier layer is in direct contact with the first light-emitting layer and the first hole transport layer;
the first electron barrier layer comprises a first electron barrier material, and a difference between a highest occupied molecular orbital energy level of the first electron barrier material and the highest occupied molecular orbital energy level of the first excimer complex is less than 0.3 eV; and
the first hole transport layer is made of a first hole transport material, and a difference between the highest occupied molecular orbital energy level of the first hole transport material and the highest occupied molecular orbital energy level of the first electron barrier material is less than 0.3 eV.

5. The light-emitting element as claimed in claim 1, wherein the first light-emitting unit further comprises a first hole barrier layer located on the side of the first light-emitting layer away from the first electrode, and a first electron transport layer located on the side of the first hole barrier layer away from the first electrode, the first hole barrier layer is in direct contact with the first light-emitting layer and the first electron transport layer;
the first hole barrier layer is made of a first hole barrier material, and a difference between a lowest unoccupied molecular orbital energy level of the first hole barrier material and the lowest unoccupied molecular orbital energy level of the first excimer complex is less than 0.3 eV; and
the first electron transfer layer is made of a first electron transfer material, and a difference between a lowest unoccupied molecular orbital energy level of the first electron transfer material and the lowest unoccupied molecular orbital energy level of the first hole barrier material is less than 0.3 eV.

6. The light-emitting element as claimed in claim 1, wherein the second light-emitting unit further comprises a second hole transport layer located on the side of the second light-emitting layer near the first electrode, and the second hole transport layer is in direct contact with the second light-emitting layer.

7. The light-emitting element as claimed in claim 1, wherein the second light-emitting unit comprises a second electron barrier layer and a second hole transport layer located on the side near the first electrode of the second electron barrier layer, the second electron barrier layer is in direct contact with the second light-emitting layer and the second hole transport layer.

8. The light-emitting element as claimed in claim 6, wherein the second light-emitting unit is located on the side near the second electrode of the first light-emitting unit, and a mobility of the second hole transport layer is greater than a mobility of the first hole transport layer of the first light-emitting unit.

9. The light-emitting element as claimed in claim 6, wherein the second light-emitting layer comprises a third main body material, a fourth main body material, a second guest material, and a second auxiliary material, wherein the third main body material forms a second excimer complex with the fourth main body material;
wherein a first excited triplet state energy level of the second auxiliary material is lower than a first excited triplet state energy level of the second excimer complex, and the first excited triplet state energy level of the second auxiliary material is higher than a first excited triplet state energy level of the second guest material.

10. The light-emitting element as claimed in claim 1, wherein the second light-emitting unit is located on the side near the second electrode of the first light-emitting unit, the first light-emitting unit further comprises a first electron transfer layer located on the side near the second electrode of the first light-emitting layer, and the second light-emitting unit further comprises a second electron transfer layer located on the side near the second electrode of the second light-emitting layer; and
the mobility of the second electron transfer layer is smaller than a mobility of the first electron transfer layer.

11. The light-emitting element as claimed in claim 1, wherein the charge generation layer comprises a first charge generation sublayer and a second charge generation sublayer located on the side away from the first electrode of the first charge generation sublayer; and
the first charge generation sublayer comprises a first doped material and a second doped material different from the first doped material, and the second charge generation sublayer comprises a third doped material and a fourth doped material different from the third doped material.

12. The light-emitting element as claimed in claim 11, wherein a difference between a lowest unoccupied molecular orbital energy level of the first charge generation sublayer and a highest occupied molecular orbital energy level of a second charge generation sublayer is less than 3 eV.

13. A display panel comprising a light-emitting element, the light-emitting element comprising:
a pair of electrodes, comprising a first electrode and a second electrode;
a first light-emitting unit, located between the pair of electrodes, wherein the first light-emitting unit comprises a first light-emitting layer;
a second light-emitting unit, located between the pair of electrodes, wherein the second light-emitting unit comprises a second light-emitting layer;
a charge generation layer, located between the first light-emitting unit and the second light-emitting unit; and
a first luminescent layer, comprising a first main body material, a second main body material, a first guest material, and a first auxiliary material, wherein the first main body material forms a first excimer complex with the second main body material;
wherein a first excited triplet state energy level of the first auxiliary material is lower than a first excited triplet state energy level of the first excimer complex, and the first excited triplet state energy level of the first auxiliary material is higher than a first excited triplet state energy level of the first guest material.

14. The display panel as claimed in claim 13, comprising a red light-emitting element, a green light-emitting element, and a blue light-emitting element;
wherein the green light-emitting element comprises a first green light-emitting unit electrode and a second green light-emitting unit electrode;
the green light-emitting element further comprises a first green light-emitting unit and a second green light-emitting unit, the first green light-emitting unit comprises a first green light-emitting layer and a first green light-emitting unit hole transport layer located on the side near the first green light-emitting unit electrode, the first green light-emitting layer is in direct contact with the first green light-emitting unit hole transport layer; and
the second green light-emitting unit comprises a second green light-emitting layer and a second green light-emitting unit hole transport layer located on the side of the second green light-emitting layer near the first green light-emitting unit electrode, the second green light-emitting layer is in direct contact with the second green light-emitting unit hole transport layer.

15. The light-emitting element as claimed in claim 1, wherein the first light-emitting unit further comprises a first hole transport layer located on the side near the first electrode of the first light-emitting layer, and the first hole transport layer is in direct contact with the first light-emitting layer;
the first hole transport layer comprises a first hole transport material, and a difference between a highest occupied molecular orbital energy level of the first hole transport material and a highest occupied molecular orbital energy level of the first excimer complex is less than 0.4 eV.

16. The display panel as claimed in claim 13, wherein the first light-emitting unit comprises a first electron barrier layer and a first hole transport layer located on the side near the first electrode of the first electron barrier layer, the first electron barrier layer is in direct contact with the first light-emitting layer, and the first electron barrier layer is in direct contact with the first hole transport layer;
the first electron barrier layer comprises a first electron barrier material, and a difference between a highest occupied molecular orbital energy level of the first electron barrier material and the highest occupied molecular orbital energy level of the first excimer complex is less than 0.3 eV; and
the first hole transport layer comprises a first hole transport material, and a difference between the highest occupied molecular orbital energy level of the first hole transport material and the highest occupied molecular orbital energy level of the first electron barrier material is less than 0.3 eV.

17. The display panel as claimed in claim 13, wherein the first light-emitting unit further comprises a first hole barrier layer located on the side of the first light-emitting layer away from the first electrode, and a first electron transport layer located on the side of the first hole barrier layer away from the first electrode, the first hole barrier layer is in direct contact with the first light-emitting layer and the first electron transport layer;
the first hole barrier layer is made of a first hole barrier material, and a difference between a lowest unoccupied molecular orbital energy level of the first hole barrier material and the lowest unoccupied molecular orbital energy level of the first excimer complex is less than 0.3 eV; and
the first electron transfer layer is made of a first electron transfer material, and a difference between a lowest unoccupied molecular orbital energy level of the first electron transfer material and the lowest unoccupied molecular orbital energy level of the first hole barrier material is less than 0.3 eV.

18. The display panel as claimed in claim 13, wherein the second light-emitting unit further comprises a second hole transport layer located on the side of the second light-emitting layer near the first electrode, and the second hole transport layer is in direct contact with the second light-emitting layer.

19. The display panel as claimed in claim 13, wherein the second light-emitting unit comprises a second electron barrier layer and a second hole transport layer located on the side near the first electrode of the second electron barrier layer, the second electron barrier layer is in direct contact with the second light-emitting layer, and the second electron barrier layer is in direct contact with the second hole transport layer.

20. The display panel as claimed in claim 13, wherein the second light-emitting unit is located on the side near the second electrode of the first light-emitting unit, the first light-emitting unit further comprises a first electron transfer layer located on the side near the second electrode of the first light-emitting layer, and the second light-emitting unit further comprises a second electron transfer layer located on the side near the second electrode of the second light-emitting layer; and
the mobility of the second electron transfer layer is smaller than a mobility of the first electron transfer layer.
